(19) United States
(12) Patent Application Publication
(10) Pub. No.: US 2026/0143704 A1
(43) Pub. Date: May 21, 2026

(54) METHOD FOR MANUFACTURING SEMICONDUCTOR MEMORY DEVICE

(71) Applicant: Kioxia Corporation, Tokyo (JP)

(72) Inventor: Hirotsugu KAWASHIMA, Inabe Mie (JP)

(73) Assignee: Kioxia Corporation, Tokyo (JP)

(21) Appl. No.: 19/070,229

(22) Filed: Mar. 4, 2025

(30) Foreign Application Priority Data
Nov. 18, 2024 (JP) 2024-200703

(51) Int. Cl. H10B 43/27

(52) U.S. Cl. CPC H10B 43/27

(57) ABSTRACT

A method for manufacturing a semiconductor memory device includes filling the plurality of holes with a carbon-containing layer so as to have an upper surface at a predetermined depth position from an upper end of each of the plurality of holes, forming a coating layer covering the upper surface of the carbon-containing layer in each of the plurality of holes, removing the carbon-containing layer via the coating layer, forming a resist pattern that covers a part of the plurality of holes closed by the coating layer and has an opening through which another part of the plurality of holes is exposed, and removing the coating layer that blocks another part of the plurality of holes exposed to an opening of the resist pattern, and additionally processing another part of the plurality of holes so as to increase the reaching depth of another part of the plurality of holes.

### CROSS-REFERENCE TO RELATED APPLICATIONS

This application is based upon and claims the benefit of priority from Japanese Patent Application No. 2024-200703, filed on Nov. 18, 2024; the entire contents of which are incorporated herein by reference.

### FIELD

Embodiments described herein relate generally to a method for manufacturing a semiconductor memory device.

### BACKGROUND

In a semiconductor memory device such as a three-dimensional nonvolatile memory, a plurality of conductive layers are stacked, and a plurality of contacts connected to each of the conductive layers at different depth positions are formed. Such a contact is obtained by repeating formation of a resist pattern and formation of a contact hole having a different reaching depth a plurality of times. When a resist pattern is repeatedly formed on a plurality of contact holes having different reaching depths, layer thickness control of the resist pattern is an issue.

### BRIEF DESCRIPTION OF THE DRAWINGS

FIG. 1 is a cross-sectional view illustrating a schematic configuration example of a semiconductor memory device according to an embodiment;

FIGS. 2A and 2B are diagrams illustrating an example of a configuration of a semiconductor memory device according to the embodiment;

FIGS. 3A to 3C are diagrams sequentially illustrating a part of the procedure of a method for manufacturing a semiconductor memory device according to the embodiment;

FIGS. 4A and 4B are diagrams sequentially illustrating a part of the procedure of a method for manufacturing a semiconductor memory device according to the embodiment;

FIGS. 5A and 5B are diagrams sequentially illustrating a part of the procedure of a method for manufacturing a semiconductor memory device according to the embodiment;

FIGS. 6A and 6B are diagrams sequentially illustrating a part of the procedure of a method for manufacturing a semiconductor memory device according to the embodiment;

FIGS. 7A to 7C are diagrams sequentially illustrating a part of the procedure of a method for manufacturing a semiconductor memory device according to the embodiment;

FIGS. 8A to 8C are diagrams sequentially illustrating a part of the procedure of a method for manufacturing a semiconductor memory device according to the embodiment;

FIGS. 9A to 9C are diagrams sequentially illustrating a part of the procedure of a method for manufacturing a semiconductor memory device according to the embodiment;

FIGS. 10A to 10C are diagrams sequentially illustrating a part of the procedure of a method for manufacturing a semiconductor memory device according to the embodiment;

FIGS. 11A to 11C are diagrams sequentially illustrating a part of the procedure of a method for manufacturing a semiconductor memory device according to the embodiment;

FIGS. 12A to 12C are diagrams sequentially illustrating a part of the procedure of a method for manufacturing a semiconductor memory device according to the embodiment;

FIGS. 13A to 13C are diagrams sequentially illustrating a part of the procedure of a method for manufacturing a semiconductor memory device according to the embodiment;

FIGS. 14A and 14B are diagrams sequentially illustrating a part of the procedure of a method for manufacturing a semiconductor memory device according to the embodiment;

FIGS. 15A and 15B are diagrams sequentially illustrating a part of the procedure of a method for manufacturing a semiconductor memory device according to the embodiment;

FIGS. 16A and 16B are diagrams sequentially illustrating a part of the procedure of a method for manufacturing a semiconductor memory device according to the embodiment;

FIGS. 17A and 17B are diagrams sequentially illustrating a part of the procedure of a method for manufacturing a semiconductor memory device according to the embodiment;

FIGS. 18A to 18C are diagrams illustrating a part of the procedure of the method for forming a contact hole in a semiconductor memory device according to a comparative example;

FIGS. 19A to 19C are diagrams illustrating a part of the procedure of a method for manufacturing a semiconductor memory device according to a first modification of the embodiment;

FIGS. 20A to 20C are diagrams illustrating a part of the procedure of a method for manufacturing a semiconductor memory device according to a second modification of the embodiment;

FIGS. 21A to 21C are diagrams illustrating a part of the procedure of a method for manufacturing a semiconductor memory device according to a third modification of the embodiment; and

FIGS. 22A to 22C are diagrams illustrating a part of the procedure of a method for manufacturing a semiconductor memory device according to a fourth modification of the embodiment.

### DETAILED DESCRIPTION

A method for manufacturing a semiconductor memory device includes forming a stacked body in which a plurality of first insulating layers and a plurality of second insulating layers are alternately stacked one by one, forming a plurality of holes extending in the stacked body in a stacking direction of the stacked body and having different reaching depths, filling the plurality of holes with a carbon-containing layer so as to have an upper surface at a predetermined depth position from an upper end of each of the plurality of holes, forming a coating layer covering the upper surface of the carbon-containing layer in each of the plurality of holes, removing the carbon-containing layer via the coating layer, forming a resist pattern that covers a part of the plurality of holes closed by the coating layer and has an opening through which another part of the plurality of holes is exposed, and removing the coating layer that blocks the another part of the plurality of holes exposed to an opening of the resist pattern, and additionally processing the another part of the plurality of holes so as to increase the reaching depth of the another part of the plurality of holes.

Hereinafter, the embodiment of the present invention will be described in detail with reference to the drawings. Note that the present invention is not limited by the following embodiment. In addition, constituent elements in the following embodiment include those that can be easily assumed by those skilled in the art or those that are substantially the same.

### (Configuration Example of Semiconductor Memory Device)

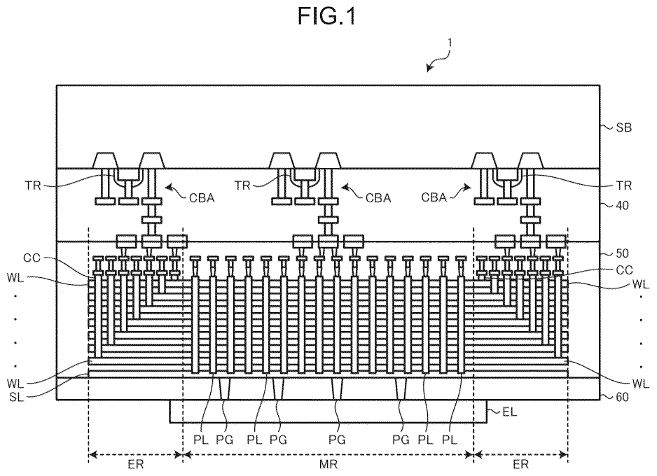

FIG. 1 is a cross-sectional view illustrating a schematic configuration example of a semiconductor memory device 1 according to the embodiment. However, in FIG. 1, hatching is omitted in consideration of visibility of the drawing.

As illustrated in FIG. 1, a semiconductor memory device 1 includes an electrode film EL, a source line SL, and a plurality of word lines WL in order from the lower side of the drawing. In addition, the semiconductor memory device 1 includes a peripheral circuit CBA provided on a semiconductor substrate SB above the plurality of word lines WL.

The source line SL is disposed on the electrode film EL via an insulating layer 60. A plurality of plugs PG are disposed in the insulating layer 60, and the source line SL and the electrode film EL maintain electrical conduction via the plugs PG. As a result, the source potential can be applied to the source line SL from the outside of the semiconductor memory device 1 via the electrode film EL and the plug PG.

A plurality of word lines WL are stacked on the source line SL. A memory region MR is disposed at the center of the plurality of word lines WL, and contact regions ER are disposed at both ends of the plurality of word lines WL.

In the memory region MR, a plurality of pillars PL penetrating the word line WL in the stacking direction are arranged. A plurality of memory cells are formed at intersections of the pillars PL and the word lines WL. As a result, the semiconductor memory device 1 is configured as, for example, a three-dimensional nonvolatile memory in which memory cells are three-dimensionally arranged in the memory region MR.

In the contact region ER, a plurality of contacts CC connected to each of the plurality of word lines WL is arranged. Note that, in the present specification, in the extending direction of the contact CC, the connection end side of the contact CC with the word line WL is defined as the lower side of the semiconductor memory device 1.

From the contact CC, a write voltage, a read voltage, and the like are applied to a memory cell included in the memory region MR at the center of the plurality of word lines WL via the word line WL at the same height position as the memory cell. In this manner, the word lines WL stacked in multiple layers are individually extracted by these contacts CC.

The plurality of word lines WL, pillars PL, and contacts CC are covered with an insulating layer 50. The insulating layer 50 also extends around the plurality of word lines WL.

The semiconductor substrate SB above the insulating layer 50 is, for example, a silicon substrate or the like. The peripheral circuit CBA including a transistor TR, wiring, and the like is disposed on the surface of the semiconductor substrate SB. Various voltages applied from the contacts CC to the memory cells are controlled by the peripheral circuits CBA electrically connected to the contacts CC. In this manner, the peripheral circuit CBA controls the electrical operation of the memory cell.

The peripheral circuit CBA is covered with an insulating layer 40, and the insulating layer 40 and the insulating layer 50 covering a stacked body LM are joined to each other, thereby forming the semiconductor memory device 1 including the configuration of the plurality of word lines WL, pillars PL, and contacts CC, and the like, and the peripheral circuit CBA.

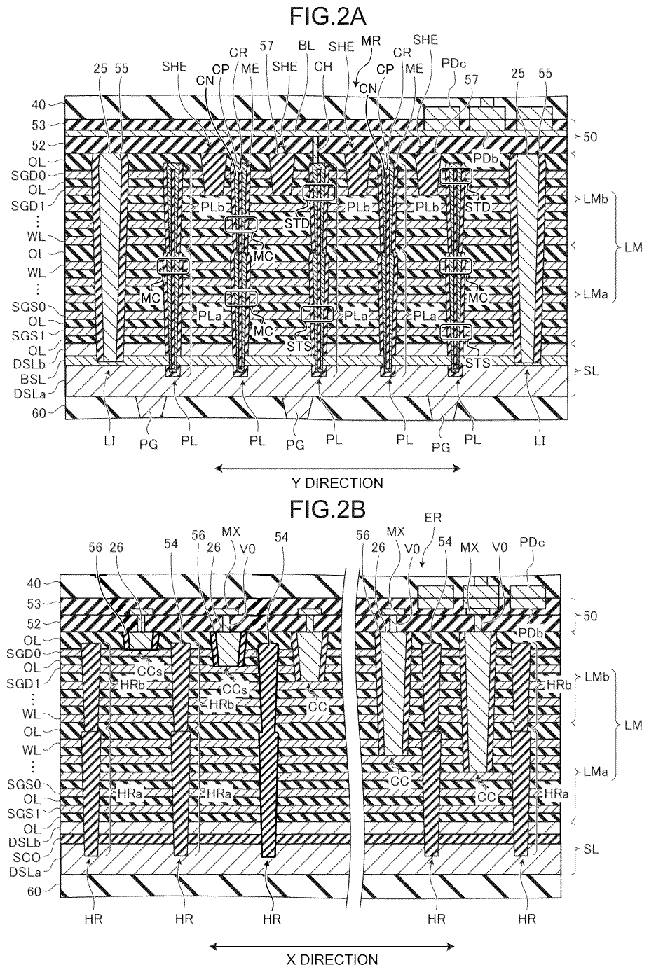

Next, a detailed configuration example of the semiconductor memory device 1 will be described with reference to FIGS. 2A and 2B. FIGS. 2A and 2B are diagrams illustrating an example of a configuration of the semiconductor memory device 1 according to the embodiment.

More specifically, FIG. 2A is a cross-sectional view along the Y direction illustrating an example of the configuration of the memory region MR. FIG. 2B is a cross-sectional view along the X direction illustrating an example of the configuration of the contact region ER. However, in FIGS. 2A and 2B, structures below the insulating layer 60 and above the insulating layer 40 are omitted.

Note that, in the present specification, both the X direction and the Y direction are directions along the direction of the surface of the word line WL, and the X direction and the Y direction are orthogonal to each other. In addition, the electrical extraction direction of the word line WL may be referred to as a first direction, and the first direction is a direction along the X direction. In addition, a direction intersecting the first direction may be referred to as a second direction, and the second direction is a direction along the Y direction. However, since the semiconductor memory device 1 may include a manufacturing error, the first direction and the second direction are not necessarily orthogonal to each other.

As illustrated in FIG. 2A, in the memory region MR, the source line SL has a multilayer structure in which, for example, a lower source line DSLa, an intermediate source line BSL, and an upper source line DSLb are stacked in this order on the insulating layer 60.

The lower source line DSLa, the intermediate source line BSL, and the upper source line DSLb are, for example, polysilicon layers or the like. Among them, at least the intermediate source line BSL may be a conductive polysilicon layer or the like in which impurities are diffused.

As illustrated in FIG. 2B, in the contact region ER, the source line SL includes an intermediate insulating layer SCO between the lower source line DSLa and the upper source line DSLb instead of the intermediate source line BSL. This is because the pillar PL to be connected with the source line SL is not arranged in the contact region ER. The intermediate insulating layer SCO is, for example, a silicon oxide layer or the like. However, the source line SL may include the intermediate source line BSL also in the contact region ER.

The stacked body LM is arranged on the source line SL. The stacked body LM includes stacked bodies LMa and LMb in which a plurality of word lines WL and a plurality of insulating layers OL are alternately stacked one by one. The stacked body LMa is disposed above the source line SL, and the stacked body LMb is disposed on the stacked body LMa.

One or more select gate lines SGS are disposed through the insulating layer OL below the lowermost word line WL of the stacked body LMa. In the example of FIGS. 2A and 2B, the stacked body LMa includes two select gate lines SGS0 and SGS1 in order from the upper layer side. One or more select gate lines SGD are disposed through the insulating layer OL above the uppermost word line WL of the stacked body LMb. In the example of FIGS. 2A and 2B, the stacked body LMb includes two select gate lines SGD0 and SGD1 in order from the upper layer side.

However, the number of word lines WL and select gate lines SGD and SGS stacked in the stacked body LM is arbitrary.

The word line WL and the select gate lines SGD and SGS as the plurality of conductive layers are, for example, a tungsten layer or a molybdenum layer. The plurality of insulating layers OL are, for example, silicon oxide layers.

The uppermost insulating layer OL of each of the stacked bodies LMa and LMb is thicker than, for example, the other insulating layers OL in the stacked bodies LMa and LMb. The uppermost insulating layer OL of the stacked body LMa is in contact with the word line WL in the lowermost layer of the stacked body LMb, and the insulating layers 52 and 53 are arranged in this order on the uppermost insulating layer OL of the stacked body LMb. The insulating layers 52 and 53 constitute a part of the insulating layer 50 described above, and the upper surface of the insulating layer 53 is in contact with, for example, the lower surface of the insulating layer 40 on the peripheral circuit CBA side.

As illustrated in FIG. 2A, the stacked body LM is divided in the Y direction by a plurality of plate-like contacts LI.

That is, the plate-like contacts LI are arranged in the Y direction and extend in the stacking direction of the stacked body LM and the X direction. As described above, the plate-like contact LI continuously extends in the stacked body LM including the memory region MR and the contact region ER from one end to the other end of the stacked body LM in the X direction.

In the memory region MR, the plate-like contact LI penetrates the stacked body LM and the upper source line DSLb and reaches the intermediate source line BSL. In the contact region ER, the plate-like contact LI penetrates the stacked body LM and the upper source line DSLb and reaches the intermediate insulating layer SCO.

In addition, each of the plate-like contacts LI includes an insulating layer 55 and a conductive layer 25. The insulating layer 55 is, for example, a silicon oxide layer or the like. The conductive layer 25 is, for example, a tungsten layer or a conductive polysilicon layer.

The insulating layer 55 covers the side walls of the plate-like contact LI facing each other in the Y direction. The inside of the insulating layer 55 is filled with the conductive layer 25. However, instead of the plate-like contact LI, a plate-like member filled with the insulating layer may penetrate the stacked body LM and extend in the direction along the X direction, thereby dividing the stacked body LM in the Y direction.

A plurality of separation layers SHE are disposed between the plate-like contacts LI adjacent in the Y direction. These separation layers SHE are insulating layers 57 such as a silicon oxide layer that penetrates the select gate lines SGD0 and SGD1 of the stacked body LMb, reaches the insulating layer OL immediately below the select gate line SGD1, and extends in the direction along the X direction in the memory region MR of the stacked body LM. With such a configuration, the separation layer SHE selectively separates the select gate lines SGD0 and SGD1 between the plate-like contacts LI in the Y direction.

In the memory region MR of the stacked body LM, a plurality of pillars PL penetrating the stacked body LM, the upper source line DSLb, and the intermediate source line BSL and reaching the lower source line DSLa are dispersedly arranged.

The plurality of pillars PL take, for example, a staggered periodic arrangement when viewed from the stacking direction of the stacked body LM. Each pillar PL has, for example, a circular shape, an elliptical shape, an oval shape, or the like as a cross-sectional shape in a direction along the layer direction of the stacked body LM, that is, in a direction along the XY plane.

The pillar PL includes a pillar PLa that penetrates the stacked body LMa from the uppermost insulating layer OL of the stacked body LMa and reaches the source line SL, and a pillar PLb that penetrates the stacked body LMb from the uppermost insulating layer OL of the stacked body LMb, reaches the uppermost insulating layer OL of the stacked body LMa, and is connected to the upper end of the corresponding pillar PLa.

Each of the plurality of pillars PL includes a memory layer ME extending in the stacked body LM in the stacking direction, a channel layer CN penetrating the stacked body LM and connected to the intermediate source line BSL, and a core layer CR serving as a core material of the pillar PL.

The memory layer ME is disposed on the side surface of the pillar PL except for the depth position of the intermediate source line BSL. In addition, the memory layer ME is also disposed on the bottom surface of the pillar PL reaching the depth of the lower source line DSLa. Note that the memory layer ME has a multilayer structure in which a block insulating layer, a carrier stored layer, and a tunnel insulating layer (all not illustrated) are stacked in this order from the outer peripheral side of the pillar PL.

The channel layer CN penetrates the stacked body LM, the upper source line DSLb, and the intermediate source line BSL inside the memory layer ME and reaches the depth of the lower source line DSLa. That is, the channel layer CN is disposed on the side surface and the bottom surface of the pillar PL via the memory layer ME. The core layer CR is filled further inside the channel layer CN.

However, a part of the channel layer CN is in contact with the intermediate source line BSL on the side surface, and is electrically connected to the source line SL including the intermediate source line BSL. In addition, a cap layer CP is disposed at the upper end of the channel layer CN, and is connected to a bit line BL extending in the direction along the Y direction in the insulating layer 53 via a plug CH disposed in the insulating layer 52.

Note that, in the cross section of FIG. 2A, only one pillar PL among the five pillars PL between the plate-like contacts LI adjacent in the Y direction is connected to the bit line BL via the plug CH. The other pillars PL disposed between the plate-like contacts LI are connected to the bit line BL different from the bit line BL in FIG. 2A via the plug CH different from the plug CH in FIG. 2A at positions different from the cross section in FIG. 2A.

The block insulating layer and the tunnel insulating layer of the memory layer ME, and the core layer CR are, for example, silicon oxide layers. The carrier stored layer of the memory layer ME is, for example, a silicon nitride layer or the like. The channel layer CN is, for example, a semiconductor layer such as a polysilicon layer or an amorphous silicon layer.

With the above configuration, memory cells MC are formed in portions facing the respective word lines WL on the side surfaces of the pillars PL. By being applied with a predetermined voltage from the word line WL, data is written to and read from the memory cell MC.

The data from the memory cell MC is read out to the bit line BL connected to the pillar PL. The bit line BL is connected to an electrode pad PDb disposed on the surface of the insulating layer 53. The electrode pad PDb is disposed on the surface of the insulating layer 40 and is connected to an electrode pad PDc electrically connected to the peripheral circuit CBA. As a result, the data of the memory cell MC read out to the bit line BL is processed by the peripheral circuit CBA.

In addition, with the above configuration, select gate lines STD are formed in portions facing the respective select gate lines SGD on the side surfaces of the pillars PL. In addition, select gate lines STS are formed in portions facing the respective select gate lines SGS on the side surfaces of the pillars PL. By being applied with a predetermined voltage from the select gate lines SGD and SGS, the select gates STD and STS are turned on or off, and the memory cells MC formed in the pillars PL to which these select gates STD and STS belong are brought into a selected state or a non-selected state.

As illustrated in FIG. 2B, a plurality of contacts CC and a plurality of columnar portions HR are arranged in the contact region ER.

Some of the plurality of contacts CC extend in the stacked body LMb in the stacking direction of the stacked body LM and are connected to one or more select gate lines SGD or the plurality of word lines WL included in the stacked body LMb, respectively.

Some of the plurality of contacts CC extend in the stacked bodies LMa and LMb in the stacking direction of the stacked body LM and are connected to any of the plurality of word lines WL belonging to the stacked body LMa. Although not illustrated, some other contacts CC extending in the stacked bodies LMa and LMb are also connected to one or more select gate lines SGS included in the stacked body LMa.

Each of these contacts CC has an insulating layer 56 covering the outer periphery of the contact CC, and a conductive layer 26 such as a tungsten layer or a copper layer filling the inside of the insulating layer 56.

The conductive layer 26 of the contact CC is connected to an upper layer wiring MX arranged in the insulating layer 53 via a plug V0 arranged in the insulating layer 52. The upper layer wiring MX is electrically connected to the above-described peripheral circuit CBA (see FIG. 1) via the electrode pad PDb on the surface of the insulating layer 53, the electrode pad PDC on the surface of the insulating layer 40, and the like.

Note that, in the region sandwiched by the plate-like contacts LI, the above-described plurality of separation layers SHE extend in the direction along the X direction in the memory region MR between the plate-like contacts LI, and also extend in the direction along the X direction in a portion where the plurality of contacts CC connected to the select gate line SGD is disposed in the contact region ER.

As a result, the select gate line SGD is sandwiched between the plate-like contact LI and the separation layer SHE or the two separation layers SHE on both sides in the Y direction, and the end in the X direction is selectively separated into a plurality of regions separated by the separation layer SHE. The contact CC is connected to each of a plurality of regions of the select gate line SGD separated by the plate-like contact LI and the separation layer SHE.

With such a configuration, the word lines WL and the select gate lines SGD and SGS of the respective layers can be electrically extracted.

That is, with the above configuration, a predetermined voltage can be applied from the peripheral circuit CBA to the memory cell MC via the upper layer wiring MX, the contact CC, and the word line WL to operate the memory cell MC as a memory element.

In addition, a predetermined voltage is applied from the peripheral circuit CBA to the select gates STD and STS via the upper layer wiring MX, the contact CC, and the select gate lines SGD and SGS, and the memory cell MC can be brought into a selected state or a non-selected state. At this time, the memory cell MC is in a selected state or a non-selected state for each region separated by the plate-like contact LI and the separation layer SHE.

In the contact region ER in which the plurality of contacts CC are arranged, a plurality of columnar portions HR penetrating the stacked body LM, the upper source line DSLb, and the intermediate insulating layer SCO and reaching the lower source line DSLa are arranged in a distributed manner.

The plurality of columnar portions HR take, for example, a substantially periodic arrangement in a grid shape or a staggered shape when viewed from the stacking direction of the stacked body LM. The reason why the arrangement of the plurality of columnar portions HR is substantially periodic is that since the columnar portions HR are arranged while avoiding interference with the plurality of contacts CC and the plate-like contact LI, the periodicity of the arrangement of the columnar portions HR slightly collapses around the plurality of contacts CC and the plate-like contact LI.

The respective columnar portions HR have, for example, a circular shape, an elliptical shape, an oval shape, or the like as a cross-sectional shape in a direction along the XY plane.

Each columnar portion HR includes a columnar portion HRa that penetrates the stacked body LMa from an uppermost insulating layer OLc of the stacked body LMa and reaches the source line SL, and a columnar portion HRb that penetrates the stacked body LMb from the uppermost insulating layer OLc of the stacked body LMb, reaches the uppermost insulating layer OLc of the stacked body LMa, and is connected to the upper end of the corresponding columnar portion HRa.

As will be described later, these columnar portions HR have a role of supporting these configurations when forming the stacked body LM from the stacked body in which the sacrificial layer and the insulating layer are stacked, and are dummy pillars that do not contribute to the function of the semiconductor memory device 1. Therefore, each of the columnar portions HRa and HRb is configured by a single body of the insulating layer 54 such as a silicon oxide layer, and is configured such that the columnar portion HR does not electrically affect other configurations.

Further, at the same height position of the stacked body LM, the cross-sectional area of the columnar portion HR in the direction along the XY plane may be larger than, for example, the cross-sectional area of the pillar PL in the direction along the XY plane. In addition, the pitch between the plurality of columnar portions HR may be larger than, for example, the pitch between the plurality of pillars PL. In the XY plane, the arrangement density of the columnar portions HR per unit area of the word line WL in the stacked body LM may be lower than the arrangement density of the pillars PL per unit area of the word line WL.

As described above, for example, by configuring the cross-sectional area of the pillars PL to be smaller and having a narrower pitch than that of the columnar portion HR, a large number of memory cells MC can be formed at a high density in the stacked body LM having a predetermined size, and the storage capacity of the semiconductor memory device 1 can be increased. On the other hand, since the columnar portion HR is exclusively used to support the stacked body LM, it is possible to reduce the manufacturing load of the semiconductor memory device 1 by not having a precise configuration with a small cross-sectional area and a narrow pitch like the pillars PL, for example.

### (Method for Manufacturing Semiconductor Memory Device)

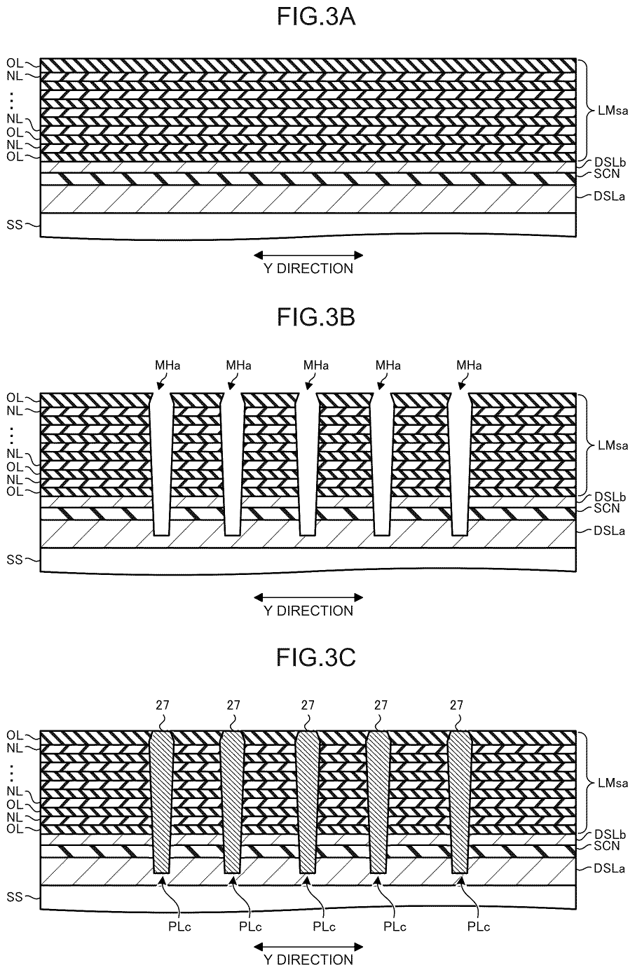

Next, a method for manufacturing the semiconductor memory device 1 according to the embodiment will be described with reference to FIGS. 3A to 17B. FIGS. 3A to 17B are diagrams sequentially illustrating a part of the procedure of a method for manufacturing the semiconductor memory device 1 according to the embodiment.

First, FIGS. 3A to 6B illustrate how the pillars PL are formed in a configuration to be the stacked body LM later. FIGS. 3A to 6B illustrate a cross section along the Y direction of the semiconductor memory device 1 in the middle of manufacturing, including a region to be the memory region MR later.

As illustrated in FIG. 3A, the lower source line DSLa, an intermediate sacrificial layer SCN, and the upper source line DSLb are formed in this order on a support substrate SS.

As the support substrate SS, a semiconductor substrate such as a silicon substrate, an insulating substrate such as a ceramic substrate, a conductive substrate, or the like can be used. The insulating layer 60 described above (see FIG. 2A and the like) may be formed on the upper surface side of the support substrate SS.

The intermediate sacrificial layer SCN is, for example, a silicon nitride layer or the like, and is a layer that is later replaced with a polysilicon layer or the like and becomes the intermediate source line BSL. Note that, although not illustrated, in a region to be the contact region ER later, the intermediate insulating layer sco is formed between the lower source line DSLa and the upper source line DSLb.

A stacked body LMsa in which a plurality of insulating layers NL and a plurality of insulating layers OL are alternately stacked one by one is formed on the upper source line DSLb. The insulating layer NL is, for example, a silicon nitride layer or the like, and functions as a sacrificial layer that is later replaced with a conductive material and becomes the word line WL or the select gate line SGS.

As illustrated in FIG. 3B, a plurality of memory holes MHa extending in the stacking direction of the stacked body LMsa is formed. The plurality of memory holes MHa penetrate the stacked body LMsa, the upper source line DSLb, and the intermediate sacrificial layer SCN, and reach the lower source line DSLa. These memory holes MHa are portions to be the pillars PLa later.

As illustrated in FIG. 3C, the memory holes MHa are filled with a sacrificial layer 27 such as an amorphous silicon layer or a CVD-carbon layer. As a result, a pillar PLc in which the plurality of memory holes MHa is filled with the sacrificial layer 27 is formed.

Note that, in the region to be the contact region ER later, a configuration in which the through hole of the stacked body LMsa is filled with the sacrificial layer to be the columnar portion HRa later is formed in parallel with the processing of FIGS. 3B and 3C.

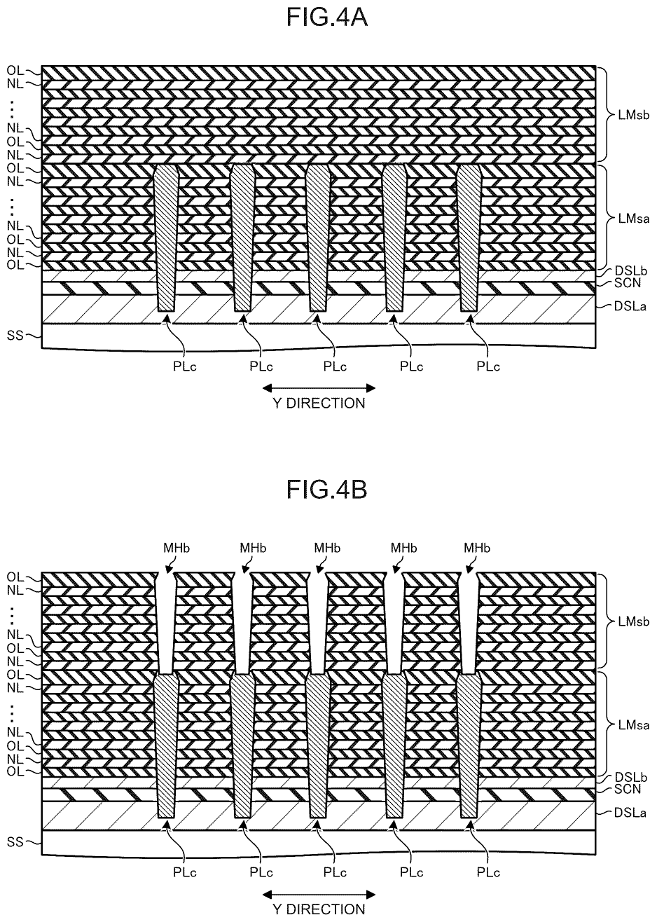

As illustrated in FIG. 4A, a stacked body LMsb covering the stacked body LMsa is formed, and in the stacked body LMsb, the plurality of insulating layers NL and the plurality of insulating layers OL are alternately stacked one by one. The insulating layer NL of the stacked body LMsb functions as a sacrificial layer that is later replaced with a conductive layer and becomes the word line WL or the select gate line SGD.

As illustrated in FIG. 4B, a plurality of memory holes MHb penetrating the stacked body LMsb and connected to the plurality of pillars PLC formed in the stacked body LMsa are formed. The memory holes MHb are portions to be the pillars PLb later.

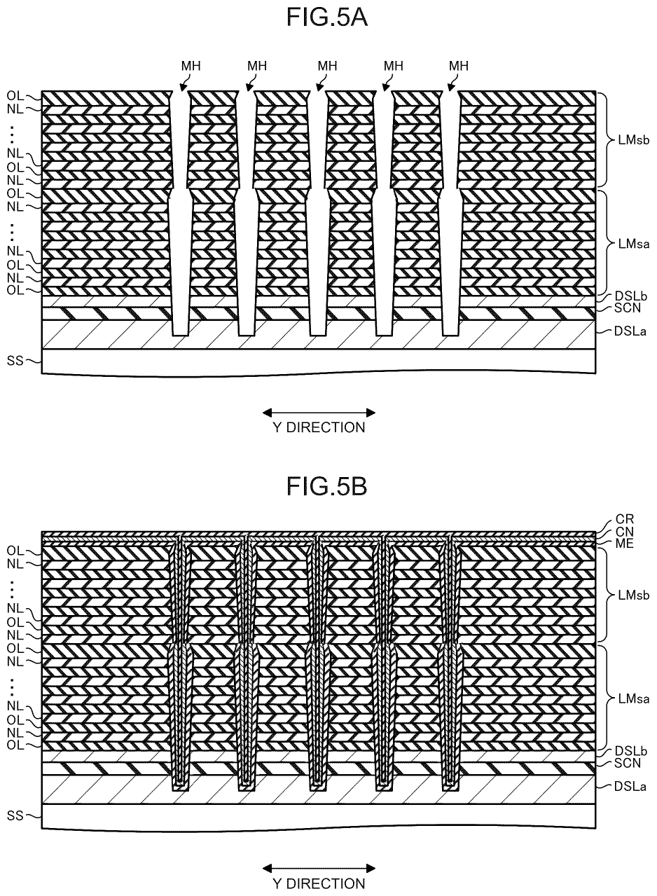

As illustrated in FIG. 5A, the sacrificial layer 27 is removed from the pillar PLC at the bottom of the memory hole MHb. As a result, the memory holes MHa are opened at the bottoms of the plurality of memory holes MHb, and a plurality of memory holes MH penetrating the stacked bodies LMsb and LMsa, the upper source line DSLb, and the intermediate sacrificial layer SCN and reaching the lower source line DSLa are formed.

Note that, in a case where the sacrificial layer 27 filled in the pillars PLC is a CVD-carbon layer or the like, the sacrificial layer 27 can be collectively removed from these pillars PLC when a mask pattern or the like used at the time of forming the memory hole MHb in FIG. 4B described above is removed by ashing or the like using oxygen plasma.

In addition, in the region to be the contact region ER later, a through hole is formed in the stacked body LMsb in parallel with the processing of FIGS. 4B to 5A, and the through hole is connected to the configuration to be the columnar portion HRa later, and the sacrificial layer is removed. Furthermore, for example, prior to the following processing of FIG. 5B, the insulating layer 54 (see FIG. 2B) is filled, for example, in the through hole penetrating the stacked bodies LMsb and LMsa, and the above-described columnar portion HR is formed.

As illustrated in FIG. 5B, a memory layer ME including a block insulating layer, a carrier stored layer, and a tunnel insulating layer (all not illustrated) in this order from the side wall side of the memory hole MH is formed on the side wall of the memory hole MH and the bottom surface from which the lower source line DSLa is exposed. The memory layer ME is also formed on the upper surface of the stacked body LMsb.

In addition, a channel layer CNb and the core layer CR are formed in this order in the memory hole MH via the memory layer ME. As a result, the memory layer ME and the channel layer CN covering the side surface and the bottom surface of the memory hole MH are formed in this order, and the core layer CR is filled in the central portion of the memory hole MH. The channel layer CN and the core layer CR are also formed in this order on the upper surface of the stacked body LMsb via the memory layer ME.

Thereafter, the core layer CR, the channel layer CN, and the memory layer ME on the upper surface of the stacked body LMsb are removed in this order. At this time, the core layer CR in the memory hole MH is retracted to form a recess at the upper end of the memory hole MH.

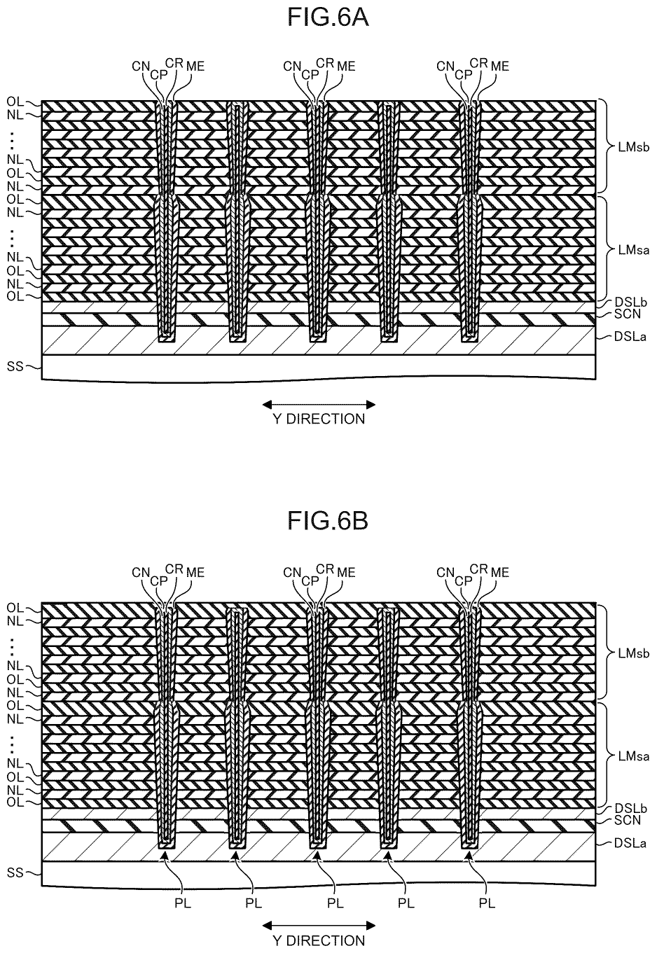

As illustrated in FIG. 6A, the cap layer CP is formed in the recess at the upper end of the memory hole MH. The cap layer CP is also formed on the upper surface of the stacked body LMsb. The cap layer CP on the upper surface of the stacked body LMsb is removed together with a part of the insulating layer OL as the uppermost layer of the stacked body LMsb.

As illustrated in FIG. 6B, the insulating layer OL as the uppermost layer of the stacked body LMsb thinned by CMP or the like is stacked. As a result, the pillar PL in which the cap layer CP is buried in the uppermost insulating layer OL is formed. However, at this point, the memory layer ME covers the entire sidewall of the pillar PL, and a part of the side surface of the channel layer CN is not exposed from the memory layer ME.

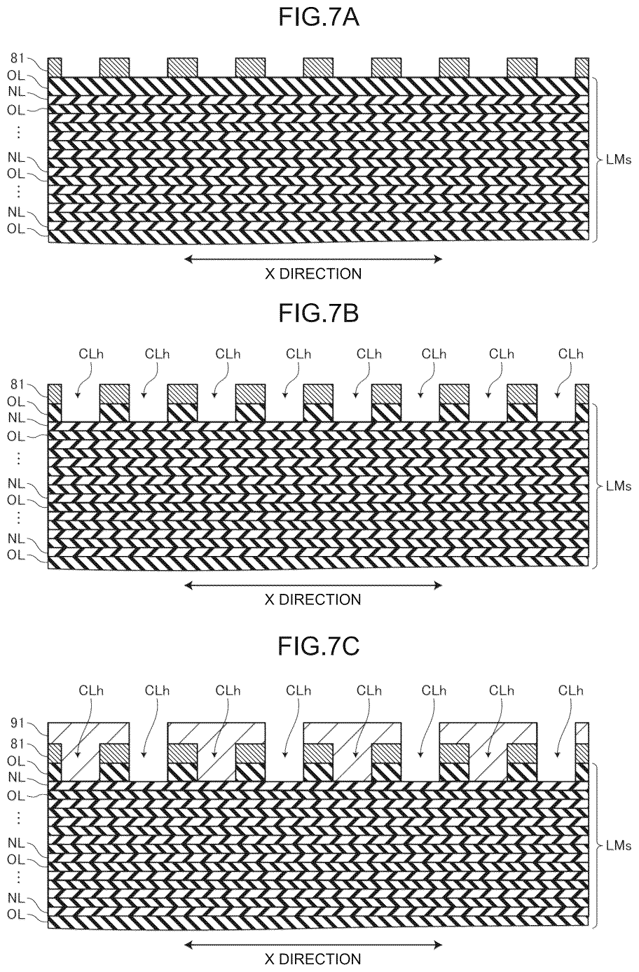

Next, a state in which the contact hole CL to be the contact CC later is formed in the stacked bodies LMsa and LMsb is illustrated in FIGS. 7A to 13C. FIGS. 7A to 13C illustrate a cross section along the X direction of the semiconductor memory device 1 in the middle of manufacturing, including a region to be the contact region ER later.

However, FIGS. 7A to 13C illustrate an example in which the contact holes CLa to CLh reaching the respective depth positions of the eight insulating layers NL of the stacked body LMs are formed as an example. In FIGS. 7A to 13C, the plurality of columnar portions HR are not illustrated.

As described below, the plurality of contact holes CL having different reaching depths are formed by forming a resist pattern a plurality of times, exposing the different contact holes CL each time, and processing the contact holes CL to different depths.

As illustrated in FIG. 7A, a hard mask pattern 81 having a plurality of openings is formed on the upper surface of the stacked body LMs. The hard mask pattern 81 is an inorganic layer that is not removed by a combustion reaction such as ashing using oxygen plasma. Each of the plurality of openings of the hard mask pattern 81 has, for example, a hole shape.

As illustrated in FIG. 7B, the upper surface of the stacked body LMs exposed from the opening of the hard mask pattern 81 is etched to remove the uppermost insulating layer OL. As a result, a plurality of contact holes CLh penetrating the uppermost insulating layer OL and reaching the insulating layer NL immediately below the insulating layer OL are formed.

As illustrated in FIG. 7C, a resist pattern 91 having a plurality of openings is formed by partially covering the upper surface of the stacked body LMs with the hard mask pattern 81 interposed therebetween. The resist pattern 91 is an organic layer such as a photoresist layer that is exposed to extreme ultra-violet (EUV) or the like and can be removed by a combustion reaction such as ashing using oxygen plasma, and is formed by a spin coating method or the like. For example, every other contact hole CLh is exposed from the opening of the resist pattern 91.

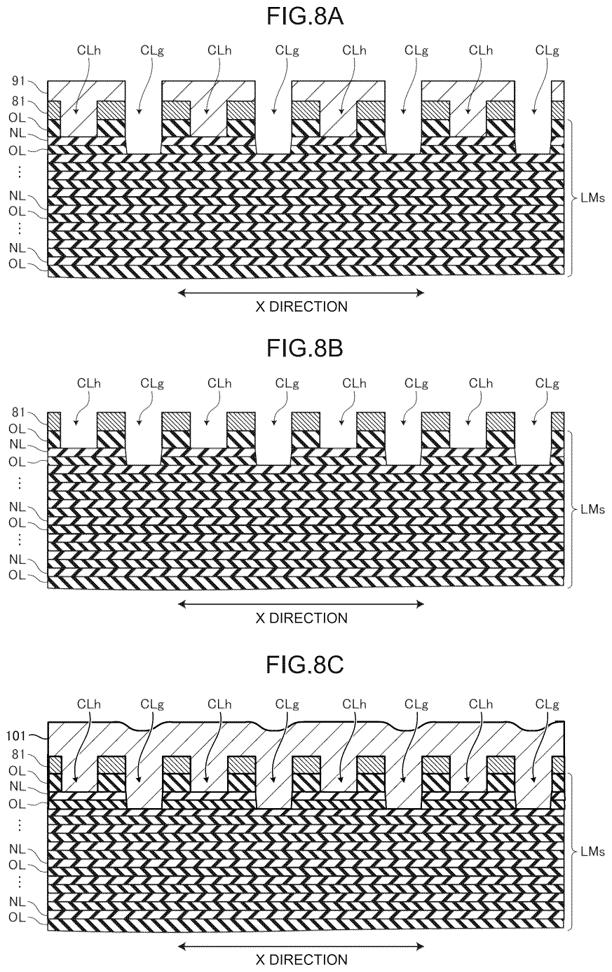

As illustrated in FIG. 8A, the contact hole CLh exposed from the opening of the resist pattern 91 is further etched to remove, for example, the pair of insulating layers NL and OL from the bottom surface of the contact hole CLh.

As a result, a plurality of contact holes CLg penetrating the stacked body LMs from the uppermost insulating layer OL to the second insulating layer OL and reaching the second insulating layer NL from the uppermost insulating layer NL are formed. These contact holes CLg are arranged every other of the plurality of contact holes CLh covered with the resist pattern 91.

That is, at this stage, the plurality of contact holes CLh and the plurality of contact holes CLg are alternately formed one by one in the stacked body LMs.

As illustrated in FIG. 8B, the resist pattern 91 is removed by ashing using oxygen plasma or the like.

As illustrated in FIG. 8C, a carbon-containing layer 101 that covers the upper surface of the stacked body LMs is formed with the hard mask pattern 81 interposed therebetween. The carbon-containing layer 101 is, for example, a photosensitive photoresist layer or the like similarly to the above-described resist pattern 91, and is formed by a spin coating method or the like. However, since the carbon-containing layer 101 is not required to have fine processability, for example, a photoresist layer or the like that is exposed to middle ultra-violet (MUV) or the like can be used as the carbon-containing layer 101.

The carbon-containing layer 101 is also filled in the plurality of contact holes CLh and CLg. At this time, the layer thickness of the carbon-containing layer 101 on the stacked body LMs tends to be slightly thin at a position where the reaching depth in the stacked body LMs overlaps the contact hole CLg deeper than the contact hole CLh in the vertical direction. This is because more carbon-containing layer 101 than contact holes CLh is required to fill contact hole CLg.

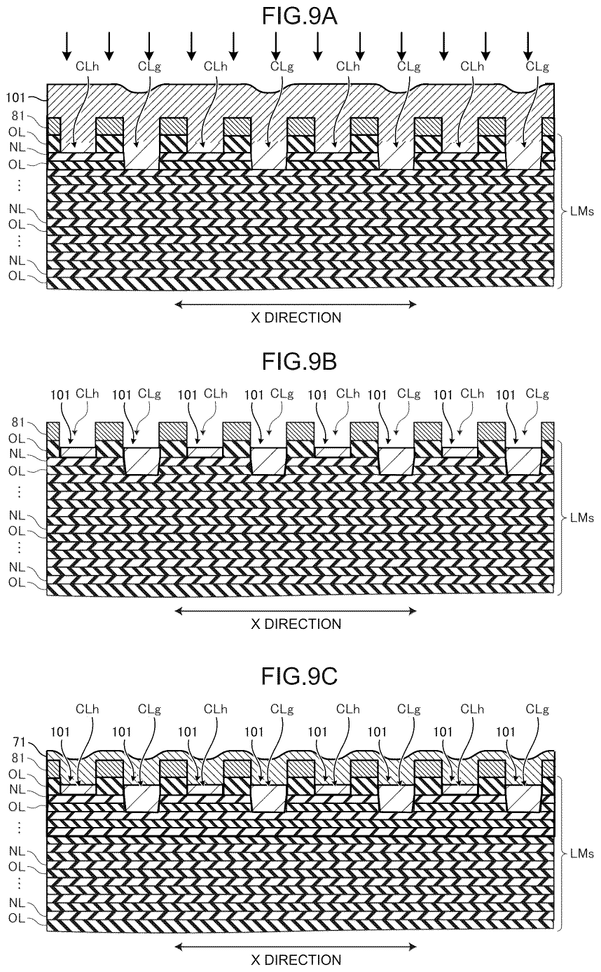

As illustrated in FIG. 9A, the carbon-containing layer 101 is exposed to a predetermined depth by irradiation with MUV light or the like.

As illustrated in FIG. 9B, the photosensitive portion of the carbon-containing layer 101 is removed by development. As a result, the carbon-containing layer 101 is filled up to a predetermined depth of each of the contact holes CLh and CLg. At this time, the upper surface of the carbon-containing layer 101 is preferably located at substantially the same depth from the upper ends of the contact holes CLh and CLg.

As illustrated in FIG. 9C, a coating layer 71 covering contact holes CLh, CLg filled with carbon-containing layer 101 is formed. The coating layer 71 is, for example, a spin-on glass (SOG) layer or the like formed by a spin coating method, and is formed on the entire upper surface of the stacked body LMs including the upper surface of the hard mask pattern 81. At this time, the coating layer 71 is preferably formed so that the density is 2.0 g/cm³ or less.

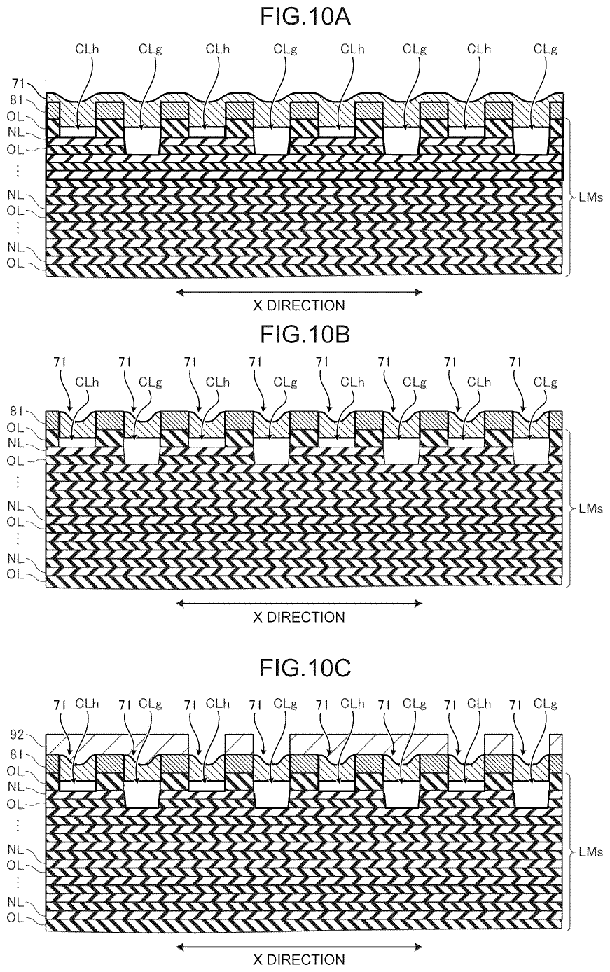

As illustrated in FIG. 10A, the carbon-containing layer 101 filled in the contact holes CLh and CLg is removed via the coating layer 71 by, for example, a combustion reaction. Examples of the combustion reaction include annealing treatment at a predetermined temperature, plasma ashing, and the like.

Since the coating layer 71 has a relatively low layer density as described above, the sublimation gas of the carbon-containing layer 101 generated by the combustion reaction can be permeated therethrough. In addition, when plasma ashing is used as the combustion reaction, the coating layer 71 can also transmit ashing gas. At this time, as the ashing gas, a gas generally known as the ashing gas, such as oxygen gas, water vapor, hydrogen gas, or NF₃ gas, can be used. Thereby, the carbon-containing layer 101 can be removed via the coating layer 71.

As illustrated in FIG. 10B, the coating layer 71 is entirely etched back and removed from the upper surface of the hard mask pattern 81. As a result, the coating layer 71 remaining in each of the contact holes CLh and CLg comes into a state like a lid that closes the upper ends of these contact holes CLh and CLg. Note that at this point, the thickness of the coating layer 71 is preferably about several tens nm to several hundreds nm, for example.

As illustrated in FIG. 10C, a resist pattern 92 having a plurality of openings is formed by partially covering the upper surface of the stacked body LMs with the hard mask pattern 81 and the coating layer 71 interposed therebetween. Similarly to the above-described resist pattern 91 and the like, the resist pattern 92 is also a photoresist layer or the like that is exposed to EUV light or the like, and is formed by a spin coating method or the like.

At this time, the upper ends of the respective contact holes CLh and CLg are closed by the coating layer 71. Further, although the coating layer 71 has a relatively low layer density, it is a solvent in which a raw material of a photoresist is dissolved, for example, and a liquid photoresist solvent does not permeate the coating layer 71. Therefore, the photoresist layer is suppressed from flowing into the contact holes CLh and CLg via the coating layer 71. As a result, the resist pattern 92 covers a part of the upper surface of the stacked body LMs with a substantially uniform thickness.

Openings of the resist pattern 92 are provided at positions overlapping the contact holes CLh and CLg in the vertical direction, for example, every other pair of one pair of contact holes CLh and CLg adjacent to each other, and the coating layer 71 that closes the contact holes CLh and CLg is exposed from these openings.

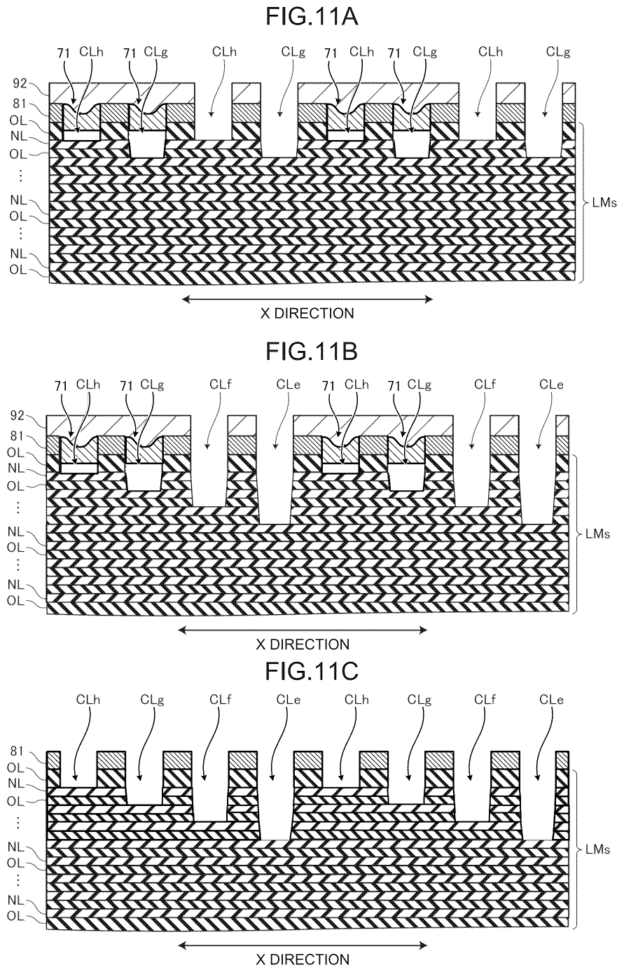

As illustrated in FIG. 11A, the coating layer 71 at the upper ends of the contact holes CLh and CLg exposed from the opening of the resist pattern 92 is removed by plasma etching or the like. As a result, these contact holes CLh and CLg are exposed from the opening of the resist pattern 92.

As illustrated in FIG. 11B, the contact holes CLh and Clg exposed from the opening of the resist pattern 92 are further etched to remove, for example, two pairs of insulating layers NL and OL from the bottom surface of the contact holes CLh and CLg, respectively.

As a result, from the contact hole Clh to be etched, a plurality of contact holes CLf penetrating the stacked body LMs from the uppermost insulating layer OL to the third insulating layer OL and reaching the third insulating layer NL from the uppermost insulating layer NL are formed.

Furthermore, from the contact hole Clg to be etched, a plurality of contact holes CLe penetrating the stacked body LMs from the uppermost insulating layer OL to the fourth insulating layer OL and reaching the fourth insulating layer NL from the uppermost insulating layer NL are formed.

As described above, by the processing so far, two pairs of the contact holes CLh to CLe in which the contact holes CLh to CLe whose reaching depths in the stacked body LMs sequentially increase are arranged in this order are formed.

As illustrated in FIG. 11C, the resist pattern 92 is removed by ashing using oxygen plasma or the like. In addition, the coating layer 71 at the upper ends of the contact holes CLh and CLg newly exposed by removing the resist pattern 92 is removed by plasma etching or the like.

Thereafter, as described below, the same processing as described above is repeated a predetermined number of times, such as formation of a coating layer that closes the plurality of contact holes CL, formation of a resist pattern, and additional etching of a part of the contact holes CL opening from the resist pattern.

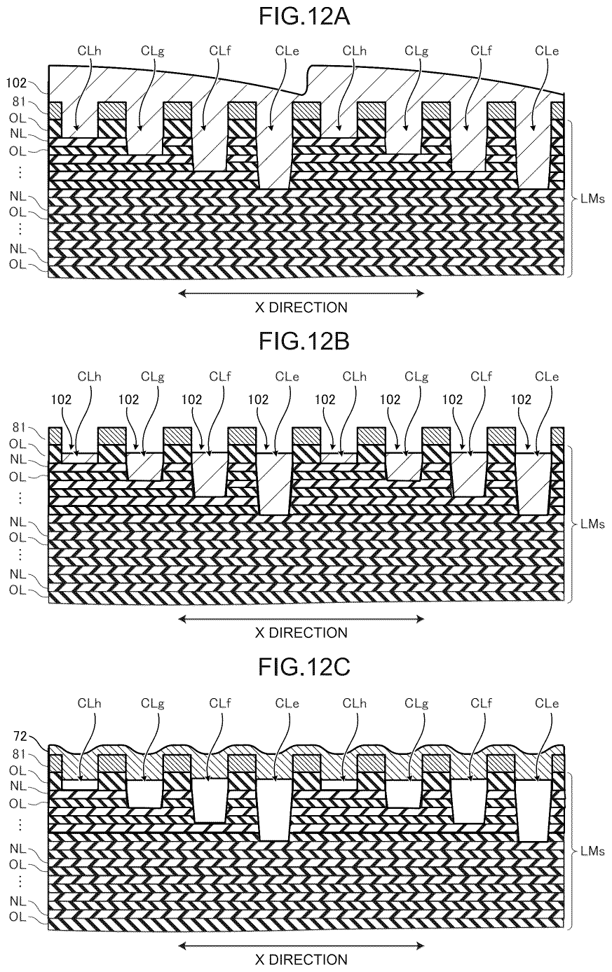

As illustrated in FIG. 12A, a carbon-containing layer 102 that covers the upper surface of the stacked body LMs is formed with the hard mask pattern 81 interposed therebetween. The carbon-containing layer 102 is, for example, a photosensitive photoresist layer or the like similarly to the above-described carbon-containing layer 101, and is formed by a spin coating method or the like.

The carbon-containing layer 102 is also filled in the plurality of contact holes CLh to CLe. At this time, since more carbon-containing layer 102 is filled as the depth of contact hole CL increases, the thickness of carbon-containing layer 102 above contact hole CL decreases. Such a layer thickness difference of the carbon-containing layer 102 is further larger than the above-described layer thickness difference of the carbon-containing layer 101 by the increase in the entire reaching depth of the contact hole CL.

Thereafter, the carbon-containing layer 102 is exposed to a predetermined depth by irradiation with MUV light or the like. At this time, it is preferable to adjust various conditions so that the photosensitive depth in the carbon-containing layer 102 having different layer thicknesses becomes substantially constant according to the reaching depth of the contact hole CL. As an example, by forming a layer having low transmittance of exposure light as the carbon-containing layer 102 and increasing the intensity of the exposure light to be irradiated, the photosensitive depths of the carbon-containing layer 102 are easily aligned.

At this time, a reticle having a pattern that is not transferred to the resist material and is not more than the resolution limit may be used in combination. That is, by setting the pattern coverage of the reticle region corresponding to the portion where the carbon-containing layer 102 is formed to be thick to zero or low and increasing the pattern coverage of the reticle region corresponding to the portion where the carbon-containing layer 102 is formed to be thin, the photosensitive depths of the carbon-containing layer 102 are aligned easily.

As illustrated in FIG. 12B, the photosensitive portion of the carbon-containing layer 102 is removed by development. As a result, the carbon-containing layer 102 is filled up to a predetermined depth of each of the contact holes CLh to CLe. At this time, by aligning the photosensitive depths as described above, the upper surface of the carbon-containing layer 102 can be aligned at substantially the same depth position from the upper ends of the contact holes CLh to CLe in the respective contact holes Clh to Cle.

As illustrated in FIG. 12C, the coating layer 72 covering the entire upper surface of the stacked body LMs including the contact holes CLh to CLe filled with the carbon-containing layer 102 and the upper surface of the hard mask pattern 81 is formed. The coating layer 72 is, for example, an SOG layer or the like formed by a spin coating method, similarly to the coating layer 71 described above. At this time, the coating layer 72 is also preferably formed so that the density is 2.0 g/cm³ or less.

Further, the carbon-containing layer 102 filled in the contact holes CLh to CLe is removed via the coating layer 72 by, for example, annealing treatment or a combustion reaction such as plasma ashing. When plasma ashing is used as the combustion reaction, a generally known gas can also be used as the ashing gas at this time.

Thereafter, the coating layer 72 is entirely etched back and removed from the upper surface of the hard mask pattern 81. As a result, the coating layer 72 remains in a lid shape that closes the upper ends of the respective contact holes CLh to CLe. Note that similarly to the coating layer 71 as described above, at this point, the thickness of the coating layer 72 is preferably about several tens nm to several hundreds nm, for example.

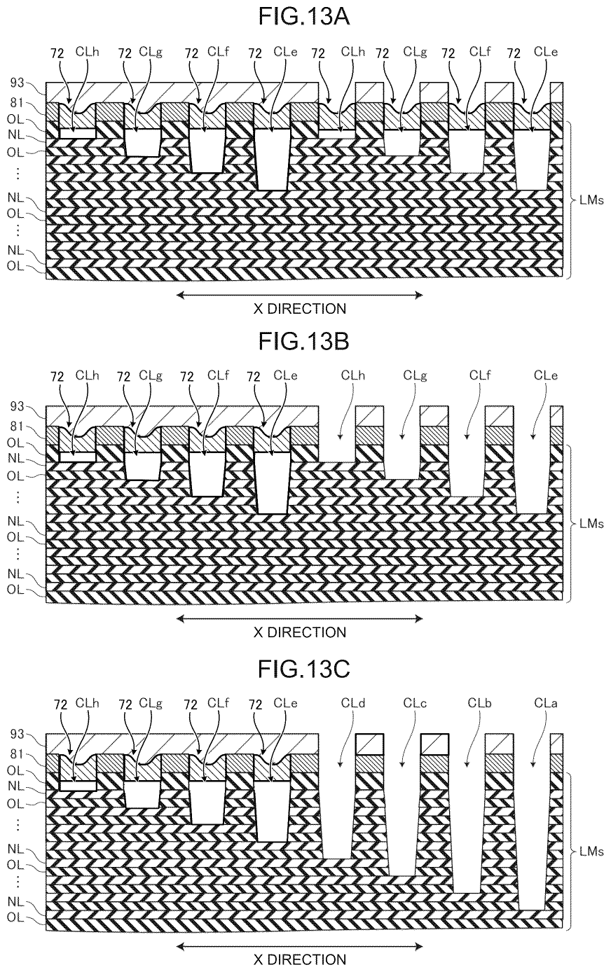

As illustrated in FIG. 13A, a resist pattern 93 having a plurality of openings is formed by partially covering the upper surface of the stacked body LMs with the hard mask pattern 81 and the coating layer 72 interposed therebetween. Similarly to the above-described resist patterns 91 and 92 and the like, the resist pattern 93 is also a photoresist layer or the like that is exposed to EUV light or the like, and is formed by a spin coating method or the like.

At this time, since the upper ends of the respective contact holes CLh to CLe are closed by the coating layer 72, the photoresist layer is suppressed from flowing into these contact holes CLh to CLe. As a result, the resist pattern 93 covers a part of the upper surface of the stacked body LMs with a substantially uniform thickness.

From the opening of the resist pattern 93, the coating layer 72 is provided at a position overlapping a pair of contact holes CLh to CLe in the vertical direction among the two pairs of contact holes CLh to CLe, and the coating layer 72 for closing the contact holes CLh to CLe is exposed from these openings.

As illustrated in FIG. 13B, the coating layer 72 at the upper ends of the contact holes CLh to CLe exposed from the opening of the resist pattern 93 is removed by plasma etching or the like. As a result, these contact holes CLh to CLe are exposed from the opening of the resist pattern 93.

As illustrated in FIG. 13C, the contact holes CLh to Cle exposed from the opening of the resist pattern 93 are further etched to remove, for example, four pairs of insulating layers NL and OL from the bottom surface of the contact holes CLh to CLe, respectively.

As a result, from the contact hole Clh to be etched, a contact hole CLd penetrating the stacked body LMs from the uppermost insulating layer OL to the fifth insulating layer OL and reaching the fifth insulating layer NL from the uppermost insulating layer NL is formed.

Furthermore, from the contact hole Clg to be etched, a contact hole CLc penetrating the stacked body LMs from the uppermost insulating layer OL to the sixth insulating layer OL and reaching the sixth insulating layer NL from the uppermost insulating layer NL is formed.

Furthermore, from the contact hole Clf to be etched, a contact hole CLb penetrating the stacked body LMs from the uppermost insulating layer OL to the seventh insulating layer OL and reaching the seventh insulating layer NL from the uppermost insulating layer NL is formed.

Furthermore, from the contact hole Cle to be etched, a contact hole CLa penetrating the stacked body LMs from the uppermost insulating layer OL to the eighth insulating layer OL and reaching the eighth insulating layer NL from the uppermost insulating layer NL is formed.

As described above, the reaching depth in the stacked body LMs sequentially increases, and the plurality of contact holes CLh to CLa reaching the eight insulating layers NL in the stacked body LMs are formed.

Thereafter, the resist pattern 93 is removed by ashing using oxygen plasma or the like. Further, the hard mask pattern 81 and the coating layer 72 remaining in some of the contact holes CLh to CLe are removed by plasma etching or the like.

In addition, the contact holes CLh to CLe are filled with a sacrificial layer such as an amorphous silicon layer or a CVD-carbon layer, and an insulating layer 56, a conductive layer 26 (see FIG. 2B and the like), and the like are formed in a later step to form a plurality of contacts CC.

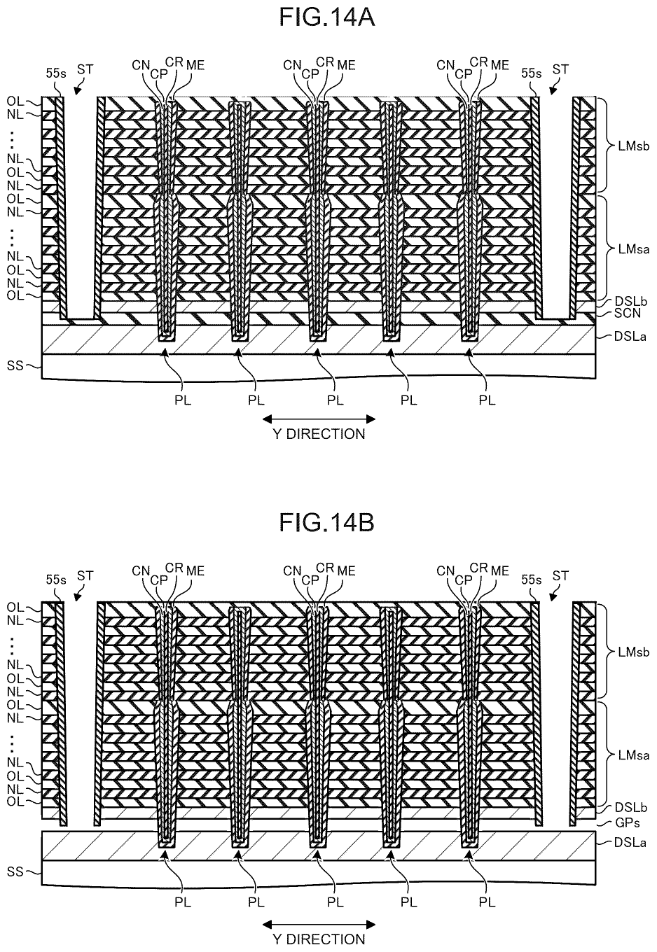

Next, FIGS. 14A to 17B illustrate a state in which the intermediate source line BSL is formed from the intermediate sacrificial layer SCN of the source line SL, and the word line WL and the like are formed from the insulating layers NL of the stacked bodies LMsa and LMsb. FIGS. 14A to 17B illustrate, similarly to FIG. 3A to 6B described above, a cross section along the Y direction of the semiconductor memory device 1 in the middle of manufacturing, including a region to be the memory region MR later.

As illustrated in FIG. 14A, a slit ST that penetrates the stacked bodies LMsb and LMsa and the upper source line DSLb and reaches the intermediate sacrificial layer SCN is formed. Further, an insulating layer 55s is formed on the side walls of the slit ST facing each other in the Y direction. The slit ST also extends in the direction along the X direction in the stacked bodies LMsa and LMsb.

As illustrated in FIG. 14B, a removal liquid of the intermediate sacrificial layer SCN such as thermal phosphoric acid is caused to flow through the slit ST whose side wall is protected by the insulating layer 55s, and the intermediate sacrificial layer SCN sandwiched between the lower source line DSLa and the upper source line DSLb is removed.

As a result, a gap layer GPs is formed between the lower source line DSLa and the upper source line DSLb. Further, a part of the memory layer ME in the outer peripheral portion of the pillar PL is exposed in the gap layer GPs. At this time, since the side wall of the slit ST is protected by the insulating layer 55s, it is suppressed that the insulating layers NL in the stacked bodies LMsa and LMsb are also removed.

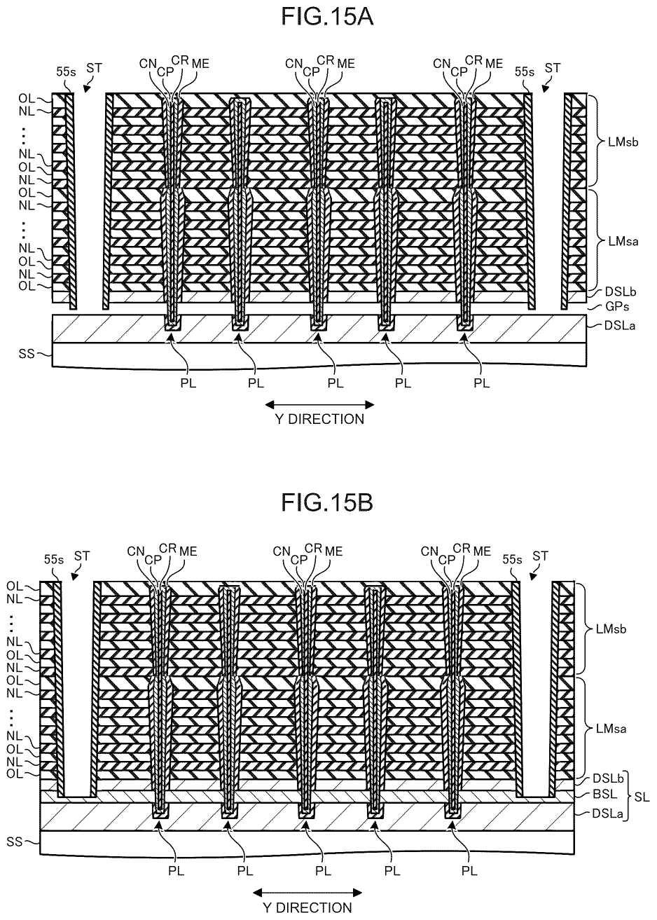

As illustrated in FIG. 15A, the chemical liquid is appropriately caused to flow into the gap layer GPS through the slit ST, and the block insulating layer, the carrier stored layer, and the tunnel insulating layer (all not illustrated) of the memory layer ME exposed in the gap layer GPs are sequentially removed. As a result, the memory layer ME is removed from a part of the side wall of the pillar PL, and a part of the channel layer CN on the inner side is exposed in the gap layer GPs.

As illustrated in FIG. 15B, a source gas such as amorphous silicon is injected from the slit ST whose side wall is protected by the insulating layer 55s, and the gap layer GPs is filled with amorphous silicon or the like. In addition, the support substrate SS is heat-treated to polycrystallize the amorphous silicon filled in the gap layer GPs, thereby forming the intermediate source line BSL containing polysilicon or the like.

As a result, a part of the channel layer CN of the pillar PL is connected to the source line SL on the side surface via the intermediate source line BSL.

Although not illustrated, the slit ST also described above also extends to a region to be the contact region ER later, and the lower end of the slit ST reaches the intermediate insulating layer SCO sandwiched between the lower source line DSLa and the upper source line DSLb. Therefore, the intermediate insulating layer SCO is not affected through the processing of FIGS. 14A to 15B described above, and remains even after the processing of FIGS. 14A to 15B described above.

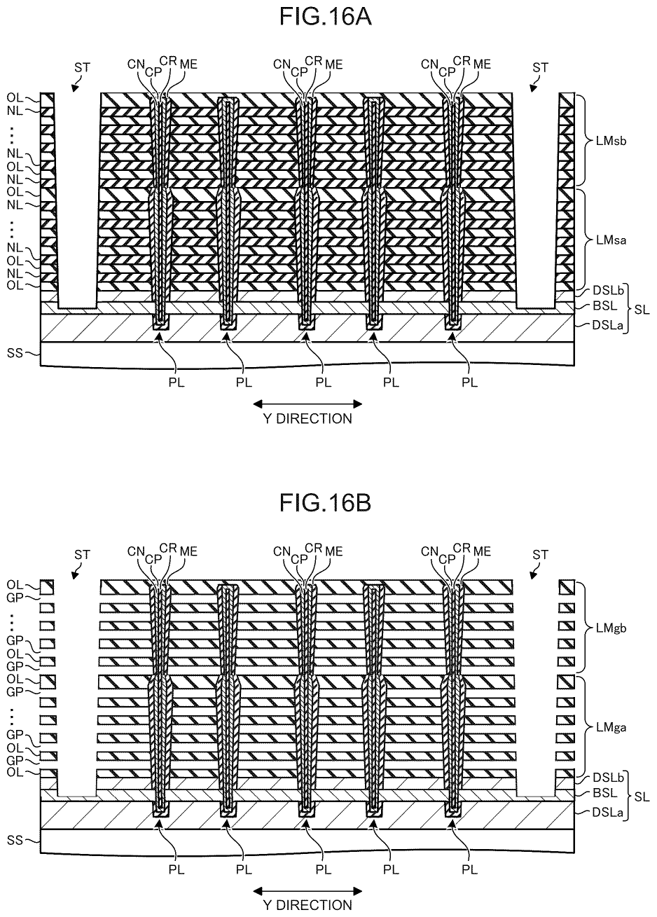

As illustrated in FIG. 16A, the insulating layer 55s on the side wall of the slit ST is removed.

As illustrated in FIG. 16B, a removal liquid of the insulating layer NL such as thermal phosphoric acid is caused to flow from the slit ST from which the insulating layer 55s has been removed into the stacked bodies LMsa and LMsb, and the insulating layers NL of the stacked bodies LMsa and LMsb are removed. As a result, the stacked bodies LMga and LMgb having the plurality of gap layers GP from which the insulating layers NL between the insulating layers OL are removed are formed.

The stacked bodies LMga and LMgb including the plurality of gap layers GP have a fragile structure. The plurality of pillars PL support such fragile stacked bodies LMga and LMgb. Although not illustrated, in the contact region ER, the above-described columnar portion HR (see FIG. 2B and the like) supports the above-described fragile stacked bodies LMga and LMgb. As a result, bending of the insulating layer OL remaining in the stacked bodies LMga and LMgb and distortion or collapse of the stacked bodies LMga and LMgb are suppressed.

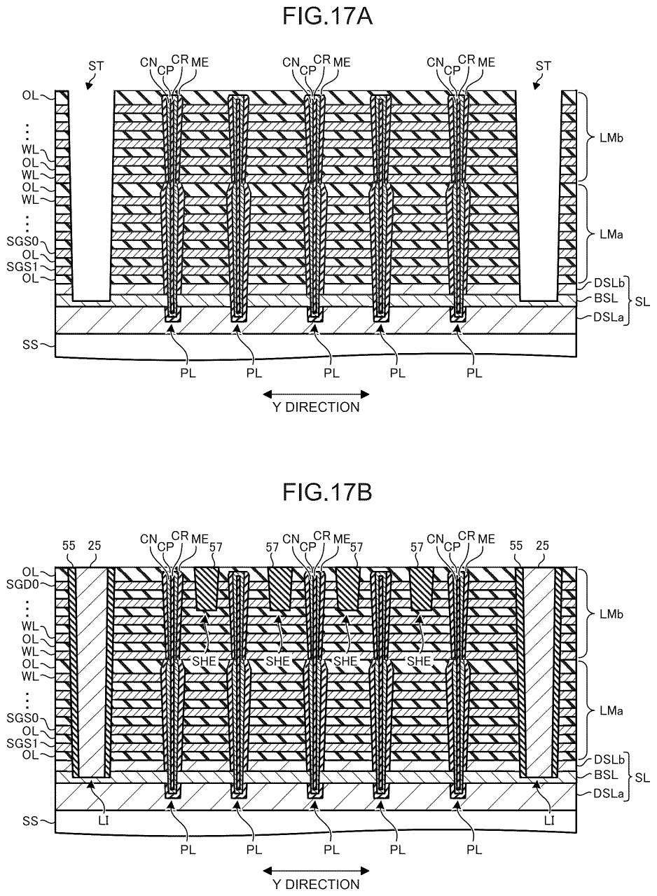

As illustrated in FIG. 17A, a source gas of a conductive material such as tungsten or molybdenum is injected from the slit ST into the stacked bodies LMga and LMgb, and the gap layers GP of the stacked bodies LMga and LMgb are filled with the conductive material to form the plurality of word lines WL and the like. As a result, the stacked body LM including the stacked bodies LMa and LMb in which the plurality of word lines WL and the like and the plurality of insulating layers OL are alternately stacked one by one is formed.

As described above, the processing of forming the intermediate source line BSL from the intermediate sacrificial layer SCN and the processing of forming the word line WL from the insulating layer NL are also referred to as replacement processing.

As illustrated in FIG. 17B, the conductive layer 25 is filled in the slit ST via the insulating layer 55 to form the plate-like contact LI. In addition, a groove penetrating one or a plurality of conductive layers including the uppermost conductive layer of the stacked body LMb is formed, and the insulating layer 57 is filled in the groove, thereby forming the separation layer SHE that partitions these conductive layers into the pattern of the select gate line SGD.

Thereafter, although not illustrated, after the sacrificial layer is removed from the plurality of contact holes CL (see FIG. 13 C and the like) formed in the contact region ER, the conductive layer 26 is filled in these contact holes CL via the insulating layer 56 to form a plurality of contacts CC connected to the plurality of word lines WL and the select gate lines SGD and SGS, respectively.

In addition, after the insulating layer 52 covering the stacked body LM is formed, a plug CH penetrating the uppermost insulating layer OL and the insulating layer 52 of the stacked body LM and connected to the cap layer CP at the upper end of the pillar PL is formed. In addition, the insulating layer 53 covering the insulating layer 52 is formed, and the bit line BL to which each plug CH is connected is formed in the insulating layer 53.

In parallel with this, a plug V0 penetrating the insulating layer 52 and connected to the upper end of the contact CC is formed. In addition, the upper layer wiring MX to which each plug V0 is connected is formed in the insulating layer 53.

For example, the plug CH and the bit line BL, and the plug V0 and the upper layer wiring MX may be collectively formed by using a dual damascene method or the like.

In addition, the peripheral circuit CBA is formed on the semiconductor substrate SB separate from the support substrate SS on which the stacked body LM is formed, and is covered with the insulating layer 40. In the insulating layer 40, a contact, a via, a wiring, or the like that leads the peripheral circuit CBA to the surface of the insulating layer 40 is formed and connected to an electrode pad or the like formed on the upper surface of the insulating layer 40.

Subsequently, the support substrate SS and the semiconductor substrate SB are bonded to each other by the insulating layers 50 and 40 which the support substrate SS and the semiconductor substrate SB have, respectively, and the electrode pads in the insulating layers 50 and 40 are connected. Thereafter, the support substrate SS is removed to expose the source line SL, and the electrode film EL is connected via the insulating layer 60 on which the plug PG is formed.

As described above, the semiconductor memory device 1 according to the embodiment is manufactured.

### Comparative Example

In a semiconductor memory device such as a three-dimensional nonvolatile memory, a plurality of contacts may be formed which penetrate a stacked body in which a plurality of word lines and the like are stacked and are connected to individual word lines and the like. The plurality of contacts are obtained by forming a resist pattern a plurality of times and forming a plurality of contact holes having different reaching depths.

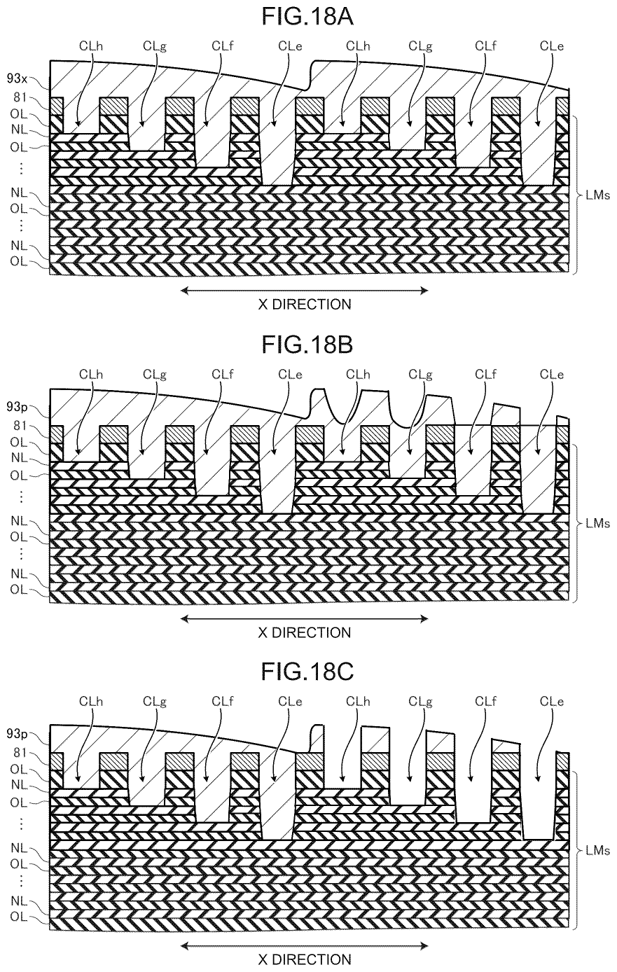

However, when a resist pattern is formed on the contact holes during formation of the plurality of contact holes, these contact holes are also filled with a resist material. At this time, since the filling amount of the resist material varies depending on the reaching depth of the contact hole, the layer thickness of the resist pattern may vary. This state is illustrated in FIGS. 18A to 18C.

FIGS. 18A to 18C are diagrams illustrating a part of the procedure of the method for forming a contact hole CL in a semiconductor memory device according to a comparative example.

FIG. 18A illustrates a state in which a photoresist layer 93x is formed on the contact holes CLh to CLe having different reaching depths in FIG. 11C of the above-described embodiment. As illustrated in FIG. 18A, the reaching depths of the contact holes CLh to CLe increase in this order, and accordingly, the layer thickness of the photoresist layer 93x formed on the contact holes CLh to CLe decreases.

As illustrated in FIG. 18B, in order to process a part of the plurality of contact holes CLh to CLe, the photoresist layer 93x is patterned by exposure and development to form a resist pattern 93p having openings on the part of the contact holes CLh to CLe. However, since the layer thickness of the photoresist layer 93x varies, the exposed state of the resist pattern 93p also varies for each layer thickness, and it is difficult to form openings having the same opening area on these contact holes CLh to CLe.

As illustrated in FIG. 18C, in order to additionally etch the contact holes CLh to CLe exposed from the openings of the resist pattern 93p, it is necessary to further remove the photoresist layer 93x filled in the contact holes CLh to CLe. At this time, the layer thickness of the entire resist pattern 93p decreases, and there is a possibility that portions not to be etched are not sufficiently protected by the subsequent additional etching of the contact holes CLh to CLe.

According to the method for manufacturing the semiconductor memory device 1 of the embodiment, the plurality of contact holes CLh to CLe is filled with the carbon-containing layer 102 so as to have the upper surface at a predetermined depth position from the upper end of each of the plurality of contact holes CLh to CLe. Further, the coating layer 72 covering the upper surface of carbon-containing layer 102 in each of the plurality of contact holes CLh to CLe is formed, and carbon-containing layer 102 is removed via the coating layer 72.

In this way, by forming the lid-like coating layer 72 that covers the upper ends of the plurality of contact holes CLh to CLe, it is possible to suppress the resist material from flowing into the contact holes CLh to CLe when the resist pattern 93 is formed. As a result, it is possible to suppress variations in the layer thickness of the resist pattern 93 on the plurality of contact holes CLh to CLe having different reaching depths. As a result, it is possible to make the opening area substantially uniform by aligning the focus positions at the individual opening positions of the resist pattern 93.

Table 1 below shows an example of focus offset values at the time of exposure of a photoresist layer in the above-described comparative example and an example in which the above-described embodiment is applied to a sample substrate. The focus offset value is a difference from a focus value at which the opening area of the resist pattern formed in a region where the contact hole is not formed, that is, at a position where there is no possibility that the resist material flows into the contact hole is maximum or minimum.

TABLE 1

| | | Comparative |
|---|---|---|
| | Example | example |
| Cont. non-formed | ±0.00 μm | ±0.00 μm |
| region | | |
| Shallow hole Cont. | ±0.00 μm | +0.12 μm |
| region | | |
| Deep hole Cont. region | ±0.00 μm | +0.21 μm |

In the region where the contact hole is not formed, a region where the contact hole having a small reaching depth is formed (shallow hole Cont. region), and a region where the contact hole having a large reaching depth is formed (deep hole Cont. region) shown in Table 1, the thickness of the photoresist layer varies in the above-described comparative example, and thus, the focus offset value during exposure also varies. Therefore, there is a possibility that a plurality of opening areas vary, or some of the opening areas are not opened. On the other hand, in the embodiment, since the variation in the layer thickness of the photoresist layer is suppressed, the focus offset values are all equal in the plurality of regions.

In addition, according to the configuration of the above-described embodiment, since the carbon-containing layer 102 is removed after the coating layer 72 that covers the plurality of contact holes CLh to CLe in a lid shape is formed, it is not necessary to remove the carbon-containing layer 102 and the like in the contact holes CLh to CLe after the resist pattern 93 is formed, and a decrease in the layer thickness of the resist pattern 93 is suppressed. Therefore, when additional etching is performed on the contact holes CLh to CLe, it is possible to more reliably protect a portion not to be etched.

According to the method for manufacturing the semiconductor memory device 1 of the embodiment, the coating layer 72 contains a material that allows a sublimation gas of the carbon-containing layer 102 generated by a combustion reaction to pass therethrough and does not allow a photoresist solvent that is a raw material of the resist pattern 93 to pass therethrough. Thereby, the carbon-containing layer 102 in the contact holes CLh to CLe can be removed through the coating layer 72 by annealing treatment, plasma ashing, or the like. In addition, even if the resist pattern 93 is then formed on the coating layer 72, a liquid photoresist solvent or the like is suppressed from flowing into the contact holes CLh to CLe.

According to the method for manufacturing the semiconductor memory device 1 of the embodiment, the density of the coating layer 72 is 2.0 g/cm³ or less. As described above, since the coating layer 72 has a relatively low density, the carbon-containing layer 102 in the contact holes CLh to CLe can be removed via the coating layer 72.

According to the method for manufacturing the semiconductor memory device 1 of the embodiment, the coating layer 72 is an SOG layer. The SOG layer is a layer having a low layer density formed by, for example, a spin coating method or the like. Therefore, the carbon-containing layer 102 in the contact holes CLh to CLe can be removed through the coating layer 72.

According to the method for manufacturing the semiconductor memory device 1 of the embodiment, a photoresist layer is formed as the carbon-containing layer 102, and the photoresist layer is exposed to light to a predetermined depth to remove an exposed portion of the photoresist layer. As a result, the upper surface of the carbon-containing layer 102 can be easily retracted to a predetermined depth position from the upper end of each of the plurality of contact holes CLh to CLe.

In addition, since it is not necessary to perform precise control, for example, as in patterning of the resist pattern 93 or the like, even when the layer thickness of the carbon-containing layer 102 on the contact holes CLh to CLe varies, it is easy to align the height position of the upper surface of the carbon-containing layer 102 retracted by photosensitivity.

### First Modification

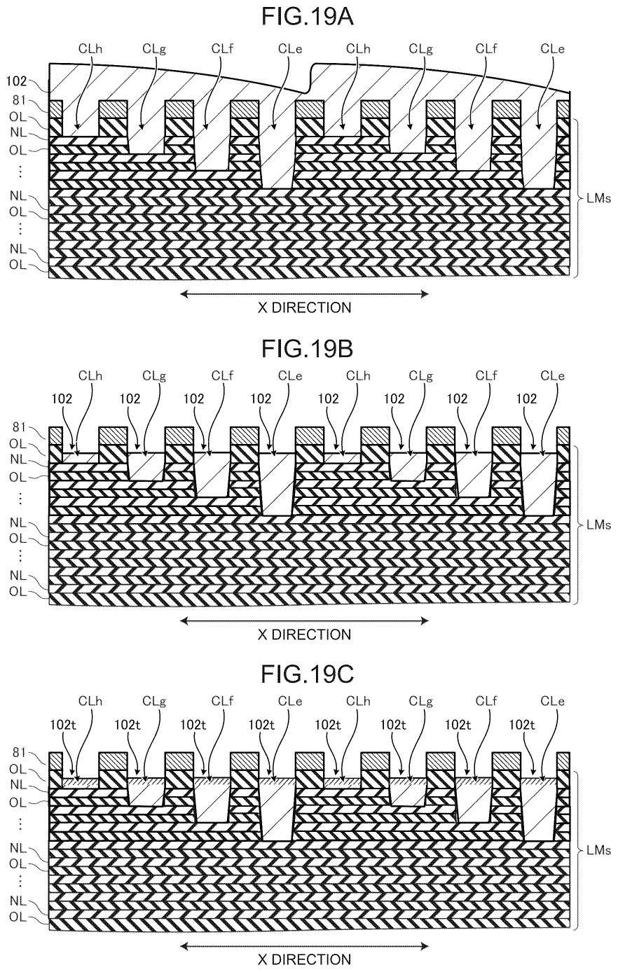

Next, a method for forming the contact hole CL in the semiconductor memory device according to a first modification of the embodiment will be described with reference to FIGS. 19A to 19C. The semiconductor memory device of the first modification is different from the above-described embodiment in that the surface treatment of the carbon-containing layer is performed before the coating layer is formed.

FIGS. 19A to 19C are diagrams illustrating a part of the procedure of a method for manufacturing the semiconductor memory device according to the first modification of the embodiment. In FIGS. 19A to 19C, the following description will be given by exemplifying a case where the carbon-containing layer 102 of the above-described embodiment is subjected to a surface treatment. That is, FIGS. 19A to 19C are diagrams corresponding to FIGS. 12A and 12B and the like of the above-described embodiment. However, in the step of forming the contact hole CL performed a plurality of times, the surface treatment may be performed every time the carbon-containing layer is formed.

In FIGS. 19A to 19C, the same reference numerals are given to the same configurations as those of the embodiment, and the description thereof may be omitted.

As illustrated in FIG. 19A, a plurality of contact holes CLh to CLe are formed in the stacked body LMs. Further, the carbon-containing layer 102 covering these contact holes CLh to Cle is formed by, for example, a spin coating method or the like.

As illustrated in FIG. 19B, the carbon-containing layer 102 is exposed to light and developed to remove a photosensitive portion of the carbon-containing layer 102.

Here, when the coating layer 72 such as an SOG layer is formed by a spin coating method or the like, a solvent in which a raw material of the SOG layer is dissolved, that is, an SOG solvent is applied onto the carbon-containing layer 102 similarly formed by a spin coating method or the like. At this time, the carbon-containing layer 102 may be partially dissolved in the SOG solvent.

Therefore, in the first modification, the surface treatment of the carbon-containing layer 102 is performed as described below.

As illustrated in FIG. 19C, by performing the surface treatment of carbon-containing layer 102, a carbon-containing layer 102t whose upper surface is cured is formed. As a method for the surface treatment of the carbon-containing layer 102, for example, it is conceivable to irradiate the upper surface of the carbon-containing layer 102 with ultraviolet rays, perform plasma treatment by reactive ion etching (RIE) using argon gas, oxygen gas, fluorocarbon gas, or the like, or dope the upper surface with a predetermined element such as argon or silicon.

By such surface treatment, on the upper surface of the carbon-containing layer 102, the C—H bond in the resin material such as the photoresist layer constituting the carbon-containing layer 102 is cut, and the carbon-containing layer is transformed into a carbon-like layer. That is, carbonization of the surface of the resin material constituting the carbon-containing layer 102 proceeds, and the upper surface of carbon-containing layer 102 is cured as described above. As a result, the upper surface of the carbon-containing layer 102 is hardly soluble in, for example, an SOG solvent.

Thereafter, similarly to the above-described embodiment, the coating layer 72 is formed on the carbon-containing layer 102t whose upper surface is cured, and the processing in and after FIG. 13A of the above-described embodiment is performed to manufacture the semiconductor memory device.

According to the method for manufacturing the semiconductor memory device of the first modification, the upper surface of the carbon-containing layer 102 located at a predetermined depth position from the upper end of each of the plurality of contact holes CLh to Cle is cured. This prevents the carbon-containing layer 102t having a cured upper surface from being dissolved in the SOG solvent or the like when the SOG layer or the like as the coating layer 72 is thereafter formed by a spin coating method or the like.

According to the method for manufacturing the semiconductor memory device of the first modification, curing the upper surface of the carbon-containing layer 102 includes at least one of irradiating the upper surface of the carbon-containing layer 102 with ultraviolet light, performing plasma treatment, or doping with a predetermined element. As a result, the photoresist layer constituting the carbon-containing layer 102 can be altered to be hardly soluble.

According to the method for manufacturing the semiconductor memory device of the first modification, the same effects as those of the method for manufacturing the semiconductor memory device 1 of the above-described embodiment are obtained.

In the first modification described above, the upper surface of the carbon-containing layer 102 is made hardly soluble by performing surface treatment and curing. However, the method for making the carbon-containing layer 102 hardly soluble is not limited to the above-described surface treatment. For example, by using a resin material having a high degree of crosslinking as the carbon-containing layer 102, the carbon-containing layer 102 can be made hardly soluble.

However, the highly crosslinked resin material needs to be formed at a high temperature, and the carbon-containing layer 102 in the contact holes CLh to CLe is easily shrunk. Therefore, when a resin material having a high degree of crosslinking is used as the carbon-containing layer 102, it is preferable to control the filling amount into the contact holes CLh to CLe in consideration of the shrinkage amount at the time of forming the carbon-containing layer 102.

### Second Modification

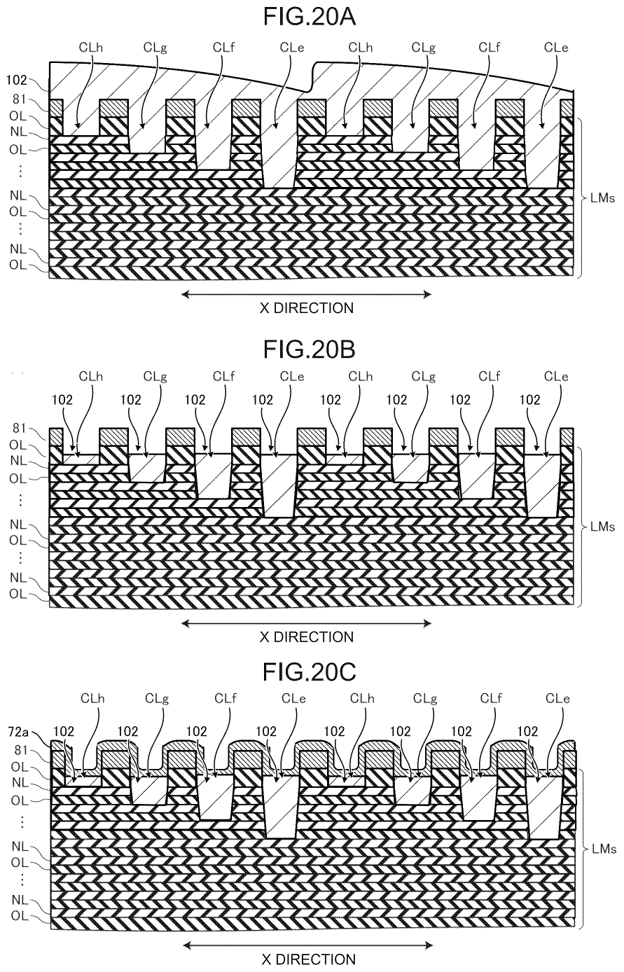

Next, a method for forming the contact hole CL in the semiconductor memory device according to a second modification of the embodiment will be described with reference to FIGS. 20A to 20C. The semiconductor memory device of the second modification is different from the above-described embodiment in that a CVD-SiO layer is formed as a coating layer instead of the SOG layer.

FIGS. 20A to 20C are diagrams illustrating a part of the procedure of a method for manufacturing the semiconductor memory device according to the second modification of the embodiment. In FIGS. 20A to 20C, the following description will be given by exemplifying a case where a coating layer 72a of the second modification is formed on the carbon-containing layer 102 of the above-described embodiment. That is, FIGS. 20A to 20C are diagrams corresponding to FIGS. 12A and 12C and the like of the above-described embodiment. However, in the step of forming the contact hole CL performed a plurality of times, the CVD-SiO layer may be used every time the coating layer is formed.

In FIGS. 20A to 20C, the same reference numerals are given to the same configurations as those of the embodiment, and the description thereof may be omitted.

As illustrated in FIG. 20A, a plurality of contact holes CLh to CLe are formed in the stacked body LMs. Further, the carbon-containing layer 102 covering these contact holes CLh to CLe is formed by, for example, a spin coating method or the like.

As illustrated in FIG. 20B, the carbon-containing layer 102 is exposed to light and developed to remove a photosensitive portion of the carbon-containing layer 102.

As illustrated in FIG. 20C, the coating layer 72a covering the entire upper surface of the stacked body LMs including the contact holes CLh to CLe filled with the carbon-containing layer 102 and the upper surface of the hard mask pattern 81 is formed. The coating layer 72a is, for example, a SiO layer or the like formed by a chemical vapor deposition (CVD) method or the like. When the CVD method is used as described above, the coating layer 72a is formed with a substantially uniform layer thickness on the upper surface of the carbon-containing layer 102 and the side walls and the upper surface of the hard mask pattern 81.

In addition, the CVD-SiO layer is, for example, a denser layer than the above-described SOG layer and the like, but is preferably formed so that the layer density is 2.0 g/cm³ or less even when the CVD-SiO layer is used as the coating layer 72a. In addition, the coating layer 72a is preferably formed to have a layer thickness of about several tens nm at the stage of being entirely etched back in the subsequent process and processed into a lid shape for closing the individual contact holes CLh to CLe.

By configuring the coating layer 72a as described above, even in the configuration of the second modification, the carbon-containing layer 102 can be removed via the coating layer 72a using annealing treatment, plasma ashing, or the like.

In addition, it is preferable to use a low-temperature CVD method for forming the coating layer 72a so that the carbon-containing layer 102 filled in the contact holes CLh to Cle is not deteriorated. Further, the coating layer 72a can be formed more precisely by using an atomic layer deposition (ALD) method or the like which is one form of the CVD method.

Thereafter, similarly to the above-described embodiment, the carbon-containing layer 102 is removed via the coating layer 72a, and the processing of FIG. 13A and subsequent drawings of the above-described embodiment is performed to manufacture the semiconductor memory device.

According to the method for manufacturing the semiconductor memory device of the second modification, the coating layer 72a is a CVD-SiO layer. As a result, the coating layer 72a can be formed on the carbon-containing layer 102 without concern of dissolution of the carbon-containing layer 102.

According to the method for manufacturing the semiconductor memory device of the second modification, the same effects as those of the method for manufacturing the semiconductor memory device 1 of the above-described embodiment are obtained.

### Third Modification

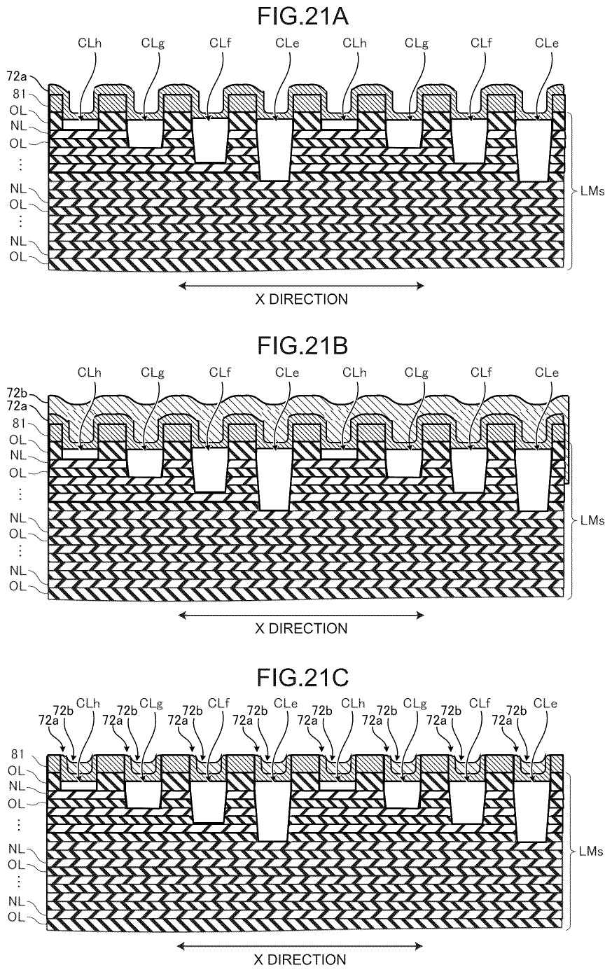

Next, a method for forming the contact hole CL in the semiconductor memory device according to a third modification of the embodiment will be described with reference to FIGS. 21A to 21C. The semiconductor memory device of the third modification is different from the above-described embodiment in that a CVD-SiO layer is formed before a coating layer such as an SOG layer is formed.

FIGS. 21A to 21C are diagrams illustrating a part of the procedure of a method for manufacturing the semiconductor memory device according to the second modification of the embodiment. In FIGS. 21A to 21C, the following description will be given by exemplifying a case where a coating layer 72b that is an SOG layer is formed on the carbon-containing layer 102 of the above-described embodiment via the coating layer 72a that is a CVD SiO layer. That is, FIGS. 21A to 21C illustrate processing subsequent to FIGS. 20A to 20C of the second modification described above. However, in the step of forming the contact hole CL performed a plurality of times, the CVD-SiO layer may be interposed every time the coating layer that is an SOG layer is formed.

As described above, the coating layer 72a using the CVD method is formed with a substantially uniform layer thickness as a whole. Therefore, as compared with the above-described coating layer 72 using a spin coating method or the like, the surface of the coating layer 72a is likely to have unevenness due to the influence of unevenness of the hard mask pattern 81. Therefore, as described below, the coating layer 72b of the SOG layer is formed so as to overlap the coating layer 72a of the CVD-SiO layer.

As illustrated in FIG. 21A, the coating layer 72a of the above-described second modification is formed at the upper ends of the plurality of contact holes CLh to CLe, and the carbon-containing layer 102 in the contact holes CLh to CLe is removed via the coating layer 72a by annealing treatment, plasma ashing, or the like.

As illustrated in FIG. 21B, the coating layer 72b is further formed on the coating layer 72a covering the contact holes CLh to CLe. Since the coating layer 72b is an SOG layer or the like formed by a spin coating method or the like, the influence of the unevenness of the hard mask pattern 81 is alleviated by forming the coating layer 72b so as to overlap the coating layer 72a.

As illustrated in FIG. 21C, by entirely etching back the coating layers 72a and 72b, the coating layers 72a and 72b on the hard mask pattern 81 are removed, and the coating layers 72a and 72b that cover the contact holes CLh to CLe in a lid shape are obtained. As a result, the coating layers 72a and 72b having flatter surfaces as a whole are obtained.

According to the method for manufacturing the semiconductor memory device of the second modification, the coating layer 72a covering the upper surface of the carbon-containing layer 102 located at a predetermined depth position from the upper end of each of the plurality of contact holes CLh to CLe is formed. In addition, the coating layer 72b covering the plurality of contact holes CLh to CLe is formed via the coating layer 72a.

As described above, by interposing the coating layer 72a, which is a CVD SiO layer or the like, the coating layer 72b can be formed on the carbon-containing layer 102 without concern for dissolution of the carbon-containing layer 102. In addition, by covering the contact holes CLh to CLe with the coating layer 72b, which is an SOG layer or the like, through the coating layer 72a, flatness of the entire coating layers 72a and 72b can be enhanced.

According to the method for manufacturing the semiconductor memory device of the third modification, the same effects as those of the method for manufacturing the semiconductor memory device 1 of the above-described embodiment are obtained.

### Fourth Modification

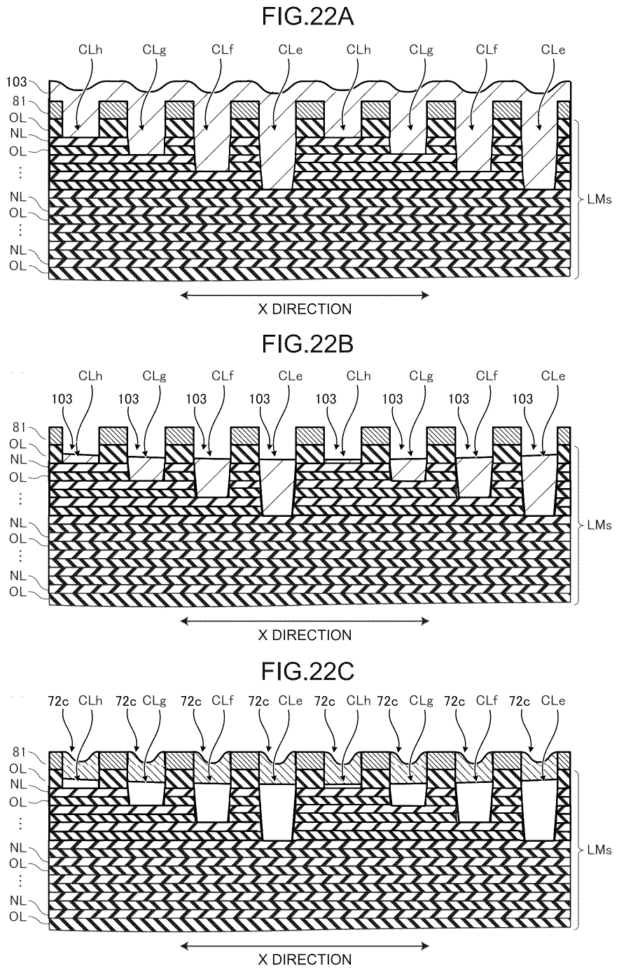

Next, a method for forming the contact hole CL in the semiconductor memory device according to a fourth modification of the embodiment will be described with reference to FIGS. 22A to 22C. The semiconductor memory device of the fourth modification is different from the above-described embodiment in that a carbon-containing layer, which is a carbon layer or the like, is formed instead of the photoresist layer or the like.

FIGS. 22A to 22C are diagrams illustrating a part of the procedure of a method for manufacturing a semiconductor memory device according to the fourth modification of the embodiment. In FIGS. 22A to 22C, the following description will be given by exemplifying a case where a carbon-containing layer 103 is formed instead of the carbon-containing layer 102 of the above-described embodiment. That is, FIGS. 22A to 22C are diagrams corresponding to FIGS. 12A and 12C and the like of the above-described embodiment. However, in the step of forming the contact hole CL performed a plurality of times, the carbon layer may be used every time the carbon-containing layer is formed.

In FIGS. 22A to 22C, the same reference numerals are given to the same configurations as those of the embodiment, and the description thereof may be omitted.

As illustrated in FIG. 22A, a plurality of contact holes CLh to CLe are formed in the stacked body LMs. Further, the carbon-containing layer 103 covering these contact holes CLh to Cle is formed. The carbon-containing layer 103 is a carbon layer containing carbon as a main component, and can be formed by a spin coating method, a CVD method, or the like.

The carbon layer does not have photosensitivity unlike the photoresist layer. However, like the photoresist layer and the like, the carbon layer can be removed by a combustion reaction such as annealing treatment or plasma ashing.

As illustrated in FIG. 22B, the surface of the carbon-containing layer 103 is polished and removed by, for example, a chemical mechanical polishing (CMP) method or the like. As a result, the carbon-containing layer 103 is filled up to a predetermined depth of each of the contact holes CLh to CLe.

At this time, the upper surface of the carbon-containing layer 103 is preferably located at substantially the same depth from the upper ends of the contact holes CLh and CLe. However, in a case where the CMP method or the like is used for removing the carbon-containing layer 103, the upper surface of the carbon-containing layer 103 may have a shape called dishing slightly recessed from the vicinity of both ends, for example, in the central portion of the plurality of contact holes CLh to CLe arranged in the X direction. This is because the polishing rate in the central portion of the plurality of contact holes CLh to CLe tends to be slightly faster than that in the vicinity of both ends thereof.

As illustrated in FIG. 22C, the coating layer 72c covering the entire upper surface of the stacked body LMs including the contact holes CLh to CLe filled with the carbon-containing layer 103 and the upper surface of the hard mask pattern 81 is formed. The coating layer 72c can also be an SOG layer using, for example, a spin coating method. As a result, even if the upper surface height of the carbon-containing layer 103 in the contact holes CLh to CLe is slightly uneven due to dishing or the like, the outermost surface of the coating layer 72c can be substantially planarized.

In addition, the carbon-containing layer 103 is removed via the coating layer 72c by annealing treatment, plasma ashing, or the like. Further, the coating layer 72c covering the entire upper surface of the stacked body LMs is entirely etched back, and the coating layer 72c that covers the upper ends of the contact holes CLh to CLe in a lid shape is obtained.

Thereafter, the processing in and after FIG. 13A of the above-described embodiment is performed, and the semiconductor memory device is manufactured.

### OTHER MODIFICATIONS

In the above-described embodiment and the like, in the step of forming the contact hole CL performed a plurality of times, the upper end of the contact hole CL is closed in a lid shape in advance with the coating layer every time the resist pattern is formed. However, the configuration of the above-described embodiment and the like may be applied only to the second half process in which the reaching depth of the contact hole CL increases and the layer thickness difference of the resist pattern easily exceeds the allowable value among the plurality of formation processes of the contact hole CL.

In addition, in the above-described embodiment and the first to fourth modifications, for example, these contact holes CL are arranged so that the reaching depth increases in the X direction. However, the arrangement order of the contact holes CL is not limited thereto. In addition, the processing order of the contact holes CL is not limited to the example of the above-described embodiment and the like, and various methods can be adopted. By applying the configuration of the above-described embodiment and the like, a resist pattern having a substantially uniform layer thickness can be formed on contact holes having different reaching depths without being affected by the arrangement order and processing order of the contact holes.

In addition, in the above-described embodiment and the first to fourth modifications, when the contact hole is additionally processed, a resist pattern using a photoresist layer or the like is used as a mask. At this time, the photoresist layer to be used as a mask may be a positive type or a negative type. When the resist pattern is formed, a bottom anti-reflective coating (BARC) layer may be interposed, and a multilayer mask structure in which a carbon layer, an SOG layer, a photoresist layer, and the like are combined may be used as the mask pattern. By applying the configuration of the above-described embodiment and the like, a resist pattern having a substantially uniform layer thickness can be formed on contact holes having different reaching depths without being affected by the type and aspect of the mask pattern.

In addition, in the above-described embodiment and the first to fourth modifications, when the resist pattern using a photoresist layer or the like is formed, exposure is performed using EUV or the like. However, the exposing the resist pattern and the method of exposure is not limited to the above example, and for example, MUV, or excimer laser light such as KrF or ArF may be used, or a method such as dry exposure or immersion exposure may be used when using ArF excimer laser light. Even in the case of using a photoresist layer as the carbon-containing layer as in the above-described embodiment and the first to third modifications, the type of exposure light and the type of exposure can be appropriately selected without being limited to MUV exposure.

Further, in the above-described embodiment and the first to fourth modifications, the contact region ER and the like are arranged at both ends in the X direction of the stacked body LM. However, the arrangement position of the contact region in the stacked body LM is not limited thereto. The contact region may be arranged, for example, in a central portion of the stacked body LM, and in this case, for example, the memory region MR can be arranged at both ends of the stacked body LM.

Further, in the above-described embodiment and the first to fourth modifications, the pillar PL is connected to the source line SL on the side surface of the channel layer CN, but the pillar PL is not limited thereto. For example, the pillar may be configured to be connected to the source line at the lower end of the channel layer by removing the memory layer on the bottom surface of the pillar.

In addition, in the above-described embodiment and the first to fourth modifications, the insulating layers NL and OL are stacked in two portions, and the stacked body IM having a two-tier structure including the stacked bodies LMa and LMb is provided. However, the stacked body may have a one-tier structure or a structure of three tiers or more. By increasing the number of tiers, the number of stacked word lines WL can be further increased.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method for manufacturing a semiconductor memory device, comprising:
forming a stacked body in which a plurality of first insulating layers and a plurality of second insulating layers are alternately stacked one by one;
forming a plurality of holes extending in the stacked body in a stacking direction of the stacked body and having different reaching depths;
filling the plurality of holes with a carbon-containing layer so as to have an upper surface at a predetermined depth position from an upper end of each of the plurality of holes;
forming a coating layer covering the upper surface of the carbon-containing layer in each of the plurality of holes;
removing the carbon-containing layer via the coating layer;
forming a resist pattern that covers a part of the plurality of holes closed by the coating layer and has an opening through which another part of the plurality of holes is exposed; and
removing the coating layer that blocks the another part of the plurality of holes exposed to the opening of the resist pattern, and additionally processing the another part of the plurality of holes so as to increase the reaching depth of the another part of the plurality of holes.

2. The method for manufacturing the semiconductor memory device according to claim 1, wherein
the removal of the carbon-containing layer is by a combustion reaction, and
the coating layer includes a material that allows a sublimation gas of the carbon-containing layer generated by the combustion reaction to pass therethrough and does not allow a photoresist solvent that is a raw material of the resist pattern to pass therethrough.

3. The method for manufacturing the semiconductor memory device according to claim 2, wherein,
a density of the coating layer is 2.0 g/cm³ or less.

4. The method for manufacturing the semiconductor memory device according to claim 2, wherein
the coating layer is an SOG layer or a CVD-SiO layer.

5. The method for manufacturing the semiconductor memory device according to claim 1, wherein
the filling the plurality of holes with the carbon-containing layer includes:
forming the carbon-containing layer covering the plurality of holes and filling the plurality of holes with the carbon-containing layer; and
reducing a thickness of the carbon-containing layer covering the plurality of holes, and retracting the upper surface of the carbon-containing layer from the upper end of each of the plurality of holes to the predetermined depth position.

6. The method for manufacturing the semiconductor memory device according to claim 5, wherein
the retracting the upper surface of the carbon-containing layer includes
forming a photoresist layer as the carbon-containing layer, and exposing the photoresist layer to light to a predetermined depth to remove an exposed portion of the photoresist layer.

7. The method for manufacturing the semiconductor memory device according to claim 6, wherein
the forming the coating layer includes:
forming a CVD-SiO layer covering the upper surface of the photoresist layer at the predetermined depth position from the upper end of each of the plurality of holes; and
forming an SOG layer as the coating layer covering the plurality of holes with the CVD-SiO layer interposed therebetween.

8. The method for manufacturing the semiconductor memory device according to claim 6, wherein
the forming the coating layer includes:
curing the upper surface of the photoresist layer at the predetermined depth position from the upper end of each of the plurality of holes; and
forming an SOG layer as the coating layer covering the cured upper surface of the carbon-containing layer.

9. The method for manufacturing the semiconductor memory device according to claim 8, wherein
the curing the upper surface of the photoresist layer includes at least one selected from the group consisting of irradiating the upper surface of the photoresist layer with ultraviolet light, performing plasma treatment, and doping with a predetermined element.

10. The method for manufacturing the semiconductor memory device according to claim 5, wherein
the retracting the upper surface of the carbon-containing layer includes
forming a carbon layer as the carbon-containing layer and etching back the carbon layer to the predetermined depth.
